(19) United States
(12) Patent Application Publication
(10) Pub. No.: US 2026/0066856 A1
(43) Pub. Date: Mar. 5, 2026

(54) METHODS AND APPARATUS TO REGULATE AN AMPLIFIER

(71) Applicant: Texas Instruments Incorporated, Dallas, TX (US)

(72) Inventors: Quan Jian Liao, Shanghai (CN); Jinlin Zhu, Shanghai (CN); Chi Cheong, Frisco, TX (US)

(21) Appl. No.: 18/819,523

(22) Filed: Aug. 29, 2024

(51) Int. Cl. H03F 3/185

(52) U.S. Cl. CPC H03F 3/1855; H03F 2200/78; H03F 2203/45074

(57) ABSTRACT

Methods, apparatus, systems, and articles of manufacture are described to regulate an amplifier. An example apparatus includes a modulator; a comparator having an input and an output, the input of the comparator coupled to an output of the modulator; a first switch having a voltage source terminal and a second terminal; a second switch having a voltage source terminal and a second terminal; a resistor having a first terminal and a second terminal, the first terminal of the resistor coupled to the second terminal of the first switch and the second terminal of the second switch; a capacitor having a terminal coupled to the second terminal of the resistor; and a buffer having an input and an output, the input of the buffer coupled to the terminal of the capacitor and the second terminal of the resistor, the output coupled to an input of the modulator.

### TECHNICAL FIELD

This description relates generally to amplifiers, and, more particularly, to methods and apparatus to regulate an amplifier.

### BACKGROUND

A computing device, such as a laptop, a tablet, a cell phone, headphones, speakers, etc., may include one or more speakers to output audio generated by a processing unit or application implemented by the computing device or a connected computing device. Some computing devices utilize class-D amplifiers. A class-D amplifier is a switching amplifier that switches back and forth between supply rails to amplify an audio signal before applying the audio signal to a speaker for output. Class D-amplifiers are efficient, small, inexpensive, and utilize less power than some other amplifiers.

### SUMMARY

An example amplifier circuit includes a modulator having an input and an output; a comparator having an input and an output, the input of the comparator coupled to the output of the modulator; a first switch having a voltage source terminal and a second terminal; a second switch having a voltage source terminal and a second terminal; a third switch having a first terminal and a second terminal, the first terminal of the third switch coupled to the second terminal of the first switch and the second terminal of the second switch; a first capacitor having a terminal, the terminal of the first capacitor coupled to the second terminal of the third switch; a fourth switch having a first terminal and a second terminal, the first terminal of the fourth switch coupled to the second terminal of the third switch and the first terminal of the first capacitor; a second capacitor having a terminal, the terminal of the second capacitor coupled to the second terminal of the fourth switch; and a buffer having an input and an output, the input of the buffer coupled to the terminal of the second capacitor and the second terminal of the fourth switch, the output of the buffer coupled to the input of the modulator. Other examples are described.

Another example amplifier circuit includes a modulator having an input and an output; a comparator having an input and an output, the input of the comparator coupled to the output of the modulator; a first switch having a voltage source terminal and a second terminal; a second switch having a voltage source terminal and a second terminal; a third switch having a first terminal and a second terminal, the first terminal of the third switch coupled to the second terminal of the first switch and the second terminal of the second switch; a first capacitor having a terminal, the terminal of the first capacitor coupled to the second terminal of the third switch; a fourth switch having a first terminal and a second terminal, the first terminal of the fourth switch coupled to the second terminal of the third switch and the first terminal of the first capacitor; a second capacitor having a terminal, the terminal of the second capacitor coupled to the second terminal of the fourth switch; and a buffer having an input and an output, the input of the buffer coupled to the terminal of the second capacitor and the second terminal of the fourth switch, the output of the buffer coupled to the input of the modulator. Other examples are described.

An example apparatus includes an amplifier configured to convert an audio signal into a pulse width modulated signal, the amplifier including: a modulator having a common mode terminal; a comparator coupled to the modulator; driver circuitry coupled to the comparator; and filtering circuitry coupled to the modulator and including: a first switch having a voltage source terminal and a second terminal; a second switch a voltage source terminal and a second terminal; a third switch having a first terminal and a second terminal, the first terminal of the third switch coupled to the second terminal of the first switch; a capacitor having a terminal, the terminal of the capacitor coupled to the second terminal of the third switch; and a controller configured to adjust a common mode voltage provided to the common mode terminal of the modulator by controlling the first switch, the second switch, and the third switch. Other examples are described.

### BRIEF DESCRIPTION OF THE DRAWINGS

FIG. 1 is an example computing device including a speaker to output audio in examples described herein.

FIG. 2 is a circuit diagram of an example of the amplifier of FIG. 1.

FIG. 3 is a circuit diagram of an example of the modulator of FIG. 2.

FIG. 4 illustrates example phases of control of switches in the amplifier of FIG. 2.

FIG. 5 is an example timing diagram corresponding to voltages at different nodes of the amplifier of FIG. 2.

FIG. 6 is a circuit diagram of an example of the common mode voltage delay controller of FIG. 2.

FIG. 7 is an example timing diagram corresponding to voltages at different nodes of the common mode voltage delay controller of FIG. 6.

FIG. 8 is a flowchart representative of example machine readable instructions or example operations that may be executed, instantiated, or performed by the common mode voltage delay controller of FIG. 2 or programmable circuitry to implement the common mode voltage delay controller of FIG. 2.

FIG. 9 illustrates an alternative example circuit for implementing common mode voltage generation circuitry of FIG. 2.

FIG. 10 is an example timing diagram corresponding to voltages at different nodes of the common mode voltage generation circuitry of FIG. 9.

FIG. 11 is an example timing diagram corresponding to voltages at different nodes of the common mode voltage generation circuitry of FIG. 9 and corresponding duty cycles of the amplifier of FIG. 2.

FIG. 12 illustrates an example state diagram corresponding to control of switches of the common mode voltage generation circuitry of FIG. 9.

FIG. 13 is a flowchart representative of example machine readable instructions or example operations that may be executed, instantiated, or performed by the common mode voltage delay controller of FIG. 9 or programmable circuitry to implement the common mode voltage delay controller of FIG. 9.

FIG. 14 is a block diagram of an example processing platform including programmable circuitry structured to execute, instantiate, or perform the example machine readable instructions or perform the example operations of FIG. 8 or 13 to implement the common mode voltage delay controller of FIG. 2 or 9.

The same reference numbers or other reference designators are used in the drawings to designate the same or similar (functionally or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines or boundaries may be idealized. In reality, the boundaries or lines may be unobservable, blended or irregular.

Computing devices may include or be connected to speakers (e.g., via a wired or wireless connection) to output audio. Such computing devices or speakers may include an amplifier to amplify the audio signal to drive the speaker to output audio corresponding to the audio signal. Class-D audio amplifiers may be used to drive speakers where high efficiency is required at high signal output powers. An example audio signal path includes an input to receive a digital audio signal (e.g., from a processor), digital to analog converter circuitry to convert the received digital audio signal to an analog signal, and a class-D amplifier to convert and amplify the analog signal to a high voltage pulse width modulated (PWM) signal that drives a speaker.

Some class D amplifiers utilize fully differential input audio signals. During startup, a state transition, etc., the class D amplifier initiates or ceases generation of a pulse width modulated signal with a particular duty cycle. For example, the duty cycle transition is from a low duty cycle to a 50 percent duty cycle during startup and from the 50 percent duty cycle to the low duty cycle during a shutdown. The duty cycle of the class D amplifier can be controlled based on a common mode voltage that is applied to a modulator of the class-D amplifier. A common mode voltage is a voltage at a node that is connected to both differential paths in an amplifier of the modulator. Thus, changing the common mode voltage adjusts the operation of the modulator. For example, a first common mode voltage applied to the modulator can result in a 10 percent duty cycle, and a second common mode voltage applied to the modulator can result in a 30 percent duty cycle. Any mismatch between the resistance, capacitance, inductance, etc., in the components in the differential class-D amplifiers may result in an increase offset at the output of the class-D amplifier. The increased offset contributes to an audible click or popping noise or other audible degradations. For example, a click or pop may be caused by direct current offset, external LC filter mismatch, resistor mismatch between corresponding resistors in different differential paths, loop stabilization, etc. The click or pop noise occurs, for example, when the audio amplifier comes in or out of shutdown, sleep, standby mode, or any other state/mode transition.

Some techniques add circuitry to control the common mode voltage linearly to slowly ramp the duty cycle of the PWM signal output by the class D amplifier to eliminate pop during dynamic transitions caused by component mismatch. For example, during startup, such circuitry can slowly ramp the duty cycle linearly from 0% to 50% during startup (and slowly ramp down the duty cycle linearly from 0% to 50% during shutdown) by slowing ramping up (or down) the common mode voltage applied to the modulator of the class D amplifier. However, such techniques result in a long startup or shutdown period (e.g., greater than 10 milliseconds (ms)). Also, such techniques require a large (e.g., greater than 1 nanoFarad) external capacitor, which adds cost and area. Moreover, such techniques may still experience a pop from 0% to 5% duty cycle because low cycle and limited rising/falling of a power stage can result in Class D modulator loop instability.

Other techniques apply a hard transition in duty cycle from an initial duty cycle to a final duty cycle by applying a hard transition from the initial common mode voltage to the final common mode voltage. In this manner, startup can occur with a small duty cycle to limit the pop and then transition to a larger duty cycle using simple switch circuitry. However, such techniques still result in a pop if there is inductor capacitor (LC) mismatch at the inputs of the speaker, for example, the larger the LC mismatch, the larger the pop.

Examples described herein adjust the duty cycle in a non-linear manner to reduce pop more than the above techniques in addition to lowering transition time without the use of a larger external capacitor. Examples described herein set an initial common mode voltage of the modulator to provide a high voltage corresponding to enabling an output signal with a low duty cycle. At the initial common mode voltage, the modulator can settle with a small PWM duty cycle, resulting in a low pop. Examples described herein use a control protocol and filtering circuitry to ramp down the VCM gradually with a delay to increase the PWM duty cycle until setting on the final PWM duty cycle of 50%. Examples described herein result in reduction in pop (e.g., 7.1-10.7 mV with a 10% LC mismatch) with fast transition time (e.g., 1 ms) and small area requirements (e.g., 0.0084-0.109 square millimeters).

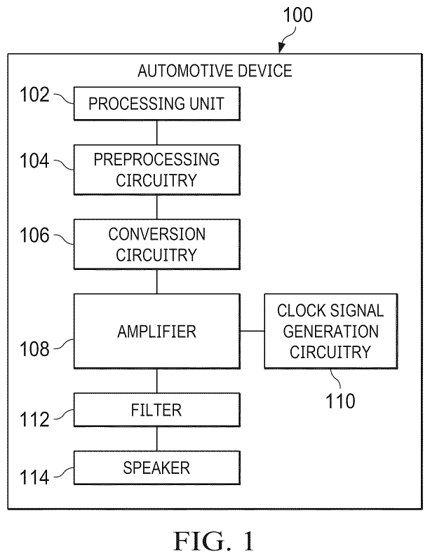

FIG. 1 illustrates an example automotive device 100. The automotive device 100 of FIG. 1 includes an example processing unit 102, example preprocessing circuitry 104, example conversion circuitry 106, an example amplifier 108, example clock signal generation circuitry 110, an example filter 112, and an example speaker 114. Alternately, one or more components of the automotive device 100 may be implemented in a different computing device, such as a computer, a laptop, a television, a cell phone, a tablet, a monitor, a receiver, a set-top-box, or any other type of computing device. Although the example automotive device 100 includes all of the components, one or more of the components may be implemented in one or more external devices. For example, the processing unit 102 and the preprocessing circuitry 104 may be implemented in a first device, such as a cell phone, laptop, a vehicle, etc. Also, the conversion circuitry 106, the amplifier 108, the clock signal generation circuitry 110, the filter 112, and the speaker 114 may be implemented in a second device, such as an infotainment unit, speakers, etc. Also, one or more of the components of the automotive device 100 may be removed or combined. Also, additional components may be added to the automotive device 100.

The processing unit 102 of FIG. 1 performs one or more functions based on applications or instructions. The processing unit 102 may be a central processing unit, a graphical processing unit, a digital signal processor, a microprocessor, a hard drive, a controller, a microcontroller, or any other processing unit. The processing unit 102 may execute or instantiate instructions or applications. The instructions or applications may generate or output an audio signal to be played via the example speaker 114. Accordingly, the processing unit 102 can output an audio signal to the speaker 114 via the preprocessing circuitry 104, the conversion circuitry 106, the amplifier 108, and the filter 112. The processing unit 102 is coupled to the preprocessing circuitry 104.

The preprocessing circuitry 104 of FIG. 1 adjusts the audio signal from the processing unit 102 to optimize the audio signal, for example to improve quality, add effects, change properties, etc. In some examples, the preprocessing circuitry 104 includes a sound card. The preprocessing circuitry 104 receives the audio signal from the processing unit 102, adjusts the audio signal, and passes the adjusted audio signal to the conversion circuitry 106. The preprocessing circuitry 104 is coupled to the processing unit 102 and the conversion circuitry 106.

The conversion circuitry 106 of FIG. 1 converts a digital audio signal from the preprocessing circuity 104 into an analog audio signal. The conversion circuitry 106 may include a digital-to-analog converter or other components to convert the digital audio signal to the analog audio signal. The conversion circuitry 106 is coupled to the preprocessing circuitry 104 and the amplifier 108.

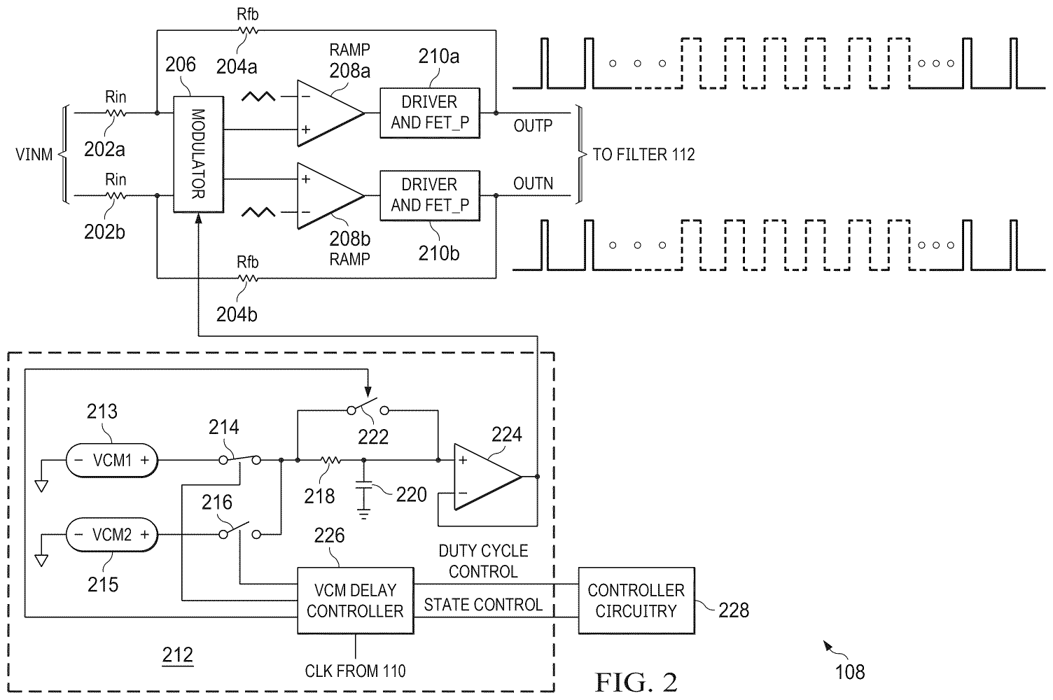

The amplifier 108 of FIG. 1 converts the analog signal to a high power PWM signal that can be used by the speaker 114 to output audio. A high power PWM signal may have an amplitude of greater than 5 Volts. As further described below, the amplifier 108 includes circuitry to reduce pops or clicks output by the speaker 114 by controlling a common mode voltage applied to a modulator of the amplifier 108. The amplifier 108 is coupled to the conversion circuitry 106, the clock signal generation circuitry 110, and the filter 112. The amplifier 108 is further described below in conjunction with FIG. 2.

The clock signal generation circuitry 110 of FIG. 1 generates a clock signal that the amplifier 108 uses to generate the common mode voltage that is used to reduce pops or clicks. The clock signal generation circuitry 110 may include an oscillator to generate the clock signal. The clock signal generation circuitry 110 is coupled to the amplifier 108.

The filter 112 of FIG. 1 is a low pass filter that filters out high frequency noise from the PWM signal generated by the amplifier 108. The filter 112 may be an LC filter that includes at least one capacitor coupled to a common terminal (e.g., a ground terminal) and at least one inductor. The filter 112 is coupled to the amplifier 108 and to the speaker 114.

The speaker 114 of FIG. 1 plays audio based on the audio signal received from the conversion circuitry 106. For example, if the audio signal corresponds to music or speech, the speaker 114 converts the audio signal into the music or speech and plays the music or speech. The speaker 114 is coupled to the amplifier 108, via the filter 112.

FIG. 2 includes an example of the amplifier 108 of FIG. 1. The amplifier 108 of FIG. 2 includes example input resistor circuitries 202a, 202b, example feedback resistor circuitries 204a, 204b, an example modulator 206, example comparators 208a, 208b, example driver circuitries 210a, 210b, example common mode voltage generation circuitry 212, and example controller circuitry 228. The common mode voltage generation circuitry 212 includes example voltage sources 213, 215, example switches 214, 216, 222, an example resistor 218, an example capacitor 220, an example buffer 224, and an example common mode voltage delay controller 226. Although FIG. 2 illustrates a fully differential structure, FIG. 2 can be implemented in a single ended system.

The input resistor circuitries 202a, 202b of FIG. 2 each include a first terminal and a second terminal. The first terminal of the input resistor circuitry 202a is coupled to the first differential output of the conversion circuitry 106. The first terminal of the input resistor circuitry 202b is coupled to the second differential output of the conversion circuitry 106. The second terminal of the resistor circuitry 202a is coupled to the resistor 228a, the feedback resistors 204a, and the modulator 206. The second terminal of the resistor circuitry 202b is coupled to the feedback resistors 204b and the modulator 206. As further described below, the amount of resistance of the resistor circuitries 202a, 202b corresponds to the gain of the amplifier 108.

The feedback resistor circuitries 204a, 204b of FIG. 2 each include a first terminal and a second terminal. The first terminal of the feedback resistor circuitry 204a is coupled to the driver circuitry 210a and the filter 112. The first terminal of the feedback resistor circuitry 204b is coupled to the driver circuitry 210b and the filter 112. The second terminal of the feedback resistor circuitry 204a is coupled to the input resistor circuitry 202a and the modulator 206. The second terminal of the feedback resistor circuitry 204b is coupled to the input resistor circuitry 202b and the modulator 206. The resistance of the feedback resistor circuitry 204a controls the gain of the modulator 206. For example, analog channel gain (G)=Rfb/Rin, where Rfb is the total resistance of the feedback resistor circuitry 204a or 204b and Rin is the total resistance of the input resistor circuitry 202a and 202b. Although FIG. 2 illustrates the resistor circuitries 202a, 202b, 204a, 204b as single resistors, one or more of the resistor circuitries 202a, 202b, 204a, 204b may be implemented by one or more resistors and/or switches. For example, the resistor circuitries 202a, 202b may be variable resistors implemented by a plurality of resistors and switches that adjust resistance based on the input audio signal to reduce noise.

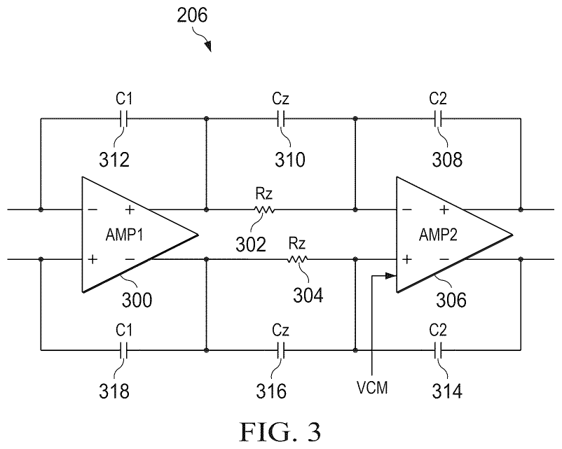

The modulator 206 of FIG. 2 includes a first differential input, a second differential input, a common mode voltage (VCM) input, a first differential output, and a second differential output. The first differential input of the modulator 206 is coupled to the input resistor circuitry 202a and the feedback resistor 204a. The second differential input of the modulator 206 is coupled to the input resistor circuitry 202b and the feedback resistor 204b. The common mode voltage (VCM) input is coupled to the output of the buffer 224. The first differential output of the modulator 206 is coupled to an input of the comparator 208a. The second differential output of the modulator 206 is coupled to an input of the comparator 208b. The modulator 206 integrates the output stage differential output signals with the input differential analog audio signals forming a closed loop to remove or reduce errors in the output signal(s). The output stage differential output signals correspond to the voltages at the OUP node and the OUTN node. The modulator 206 provides the differential output signals that correspond to the integrated output stage differential to the output signals of the driver circuitries 210a, 210b. An example of the modulator 206 is further described below in conjunction with FIG. 3.

The comparators 208a, 208b of FIG. 2 each include a first input, a second input, and an output. The first input of the comparator 208a of FIG. 2 is a non-inverting input. The first input of the comparator 208a is coupled to the first output of the modulator 206. The first input of the comparator 208b is a non-inverting input. The first input of the comparator 208b is a non-inverting input. The first input of the comparator 208b is coupled to the second output of the modulator 206. The second input of the comparator 208a is an inverting input. The second input of the comparator 208a is coupled to a triangle wave generator that provides a triangle wave. The first output of the comparator 208a is coupled to the driver circuitry 210a. The second output of the comparator 208b is coupled to the driver circuitry 210b. The comparators 208a, 208b compare the differential output signals of the modulator 206 to high frequency signal(s), for example one or more triangle waves. For example, if the triangle wave is higher than the analog voltage, the comparator 208a provides a logic high voltage. Otherwise, the comparator 208a provides a logic low voltage. The output signals of the comparators 208a, 208b correspond to one or more series of pulses that are used to drive transistors to generate a high voltage PWM signal to apply to the speaker 114.

The driver circuitries 210a, 210b of FIG. 2 each include an input and an output. The input of the driver circuitry 210a is coupled to the output of the comparator 208a. The input of the driver circuitry 210b is coupled to the output of the comparator 208b. The output of the driver circuitry 210a is coupled to the feedback resistor circuitry 204a and the filter 112. The output of the driver circuitry 210b is coupled to the feedback resistor circuitry 204b and the filter 112. The driver circuitries 210a, 210b include high-power switching transistors and one or more drivers to drive the high-power switching transistors based on the one or more series of pulses from the comparators 208a, 208b. The output of the high-power switching transistors is one or more pulse width modulated signals that correspond to the input audio signal. The driver circuitries 210a, 210b provide the pulse width modulated signals to the filter 112.

The voltage sources 213, 215 of FIG. 2 each include a terminal. The terminal of the voltage source 213 is coupled to a first terminal of the switch 214. The terminal of the voltage source 215 is coupled to a first terminal of the switch 216. The voltage sources 213, 215 each provide a particular voltage. The voltage generated by the voltage sources 213, 215 is a common mode voltage that is eventually applied to common mode terminal of the modulator 206. The common mode voltage corresponds to a particular duty cycle. For example, the first voltage source 213 may provide a voltage that corresponds to a low duty cycle (e.g., <15%) and the second voltage source 215 may provide a voltage that corresponds to a high duty cycle (e.g., 50%). Although FIG. 2 includes two voltage sources, there may be any number of voltage sources coupled to switches that are coupled to the resistor 218 and switch 222.

The switches 214, 216 of FIG. 2 each include a first terminal, a second terminal, and a control terminal. The first terminal of the switch 214 is coupled to the first voltage source 213. The first terminal of the switch 216 is coupled to the second voltage source 215. The first terminals of the switches 214, 216 are also referred to as voltage source terminals. The second terminal of the switch 214 is coupled to the second terminal of the switch 216, the first terminal of the switch 222, and the first terminal of the resistor 218. The second terminal of the switch 216 is coupled to the second terminal of the switch 214, the first terminal of the switch 222, and the first terminal of the resistor 218. The control terminals of the switches 214, 216 are each coupled to the VCM delay controller 226. The switches 214, 216 can be individually controlled to operate as an open connection or a closed connection, as further described below. The switches 214, 216 may be implemented by transistors, for example field effect transistors.

The resistor 218 of FIG. 2 includes a first terminal and a second terminal. The first terminal of the resistor 218 is coupled to the second terminals of the switches 214, 216 and the first terminal of the switch 222. The second terminal of the resistor 218 is coupled to the second terminal of the switch 222, the first terminal of the capacitor 220, and the first input of the buffer 224. The resistor 218 and the capacitor 220 implement filtering circuitry that is used to gradually adjust between the VCM1 and VCM2 voltages.

The capacitor 220 of FIG. 2 includes a first terminal and a second terminal. The first terminal of the capacitor 220 is coupled to the second terminals of the resistor 218 and the switch 222 and the first input of the buffer 224. The second terminal of the capacitor 220 is coupled to a common terminal (e.g., a ground terminal). The capacitor 220 stores charge to generate a voltage at the first input of the buffer 224 based on the voltage from the VCM1 voltage source 213 or the VCM2 voltage source 215, depending on control of the switches 214, 216.

The switch 222 of FIG. 2 includes a first terminal, a second terminal, and a control terminal. The first terminal of the switch 222 is coupled to the second terminals of the switches 214, 216 and the first terminal of the resistor 218. The second terminal of the switch 222 is coupled to the second terminal of the resistor 218, the first terminal of the capacitor 220, and the first input of the buffer 224. The control terminal of the switch 222 is coupled to the VCM delay controller 226. The switch 222 can be controlled to operate as an open connection or a closed connection, as further described below.

The buffer 224 of FIG. 2 includes a first input, a second input, and an output. The first input of the buffer 224 is a non-inverting terminal. The first input of the buffer 224 is coupled to the second terminals of the switch 222 and the resistor 218 and the first terminal of the capacitor 220. The second input of the buffer 224 is an inverting terminal. The second input of the buffer 224 is coupled to the output of the buffer 224 and the VCM terminal of the modulator 206. The output of the buffer 224 is coupled to the second input of the buffer 224 and the VCM terminal of the modulator 206. The buffer 224 provides the voltage at the first input of the buffer 224 to the modulator 206 without drawing current from the capacitor 220.

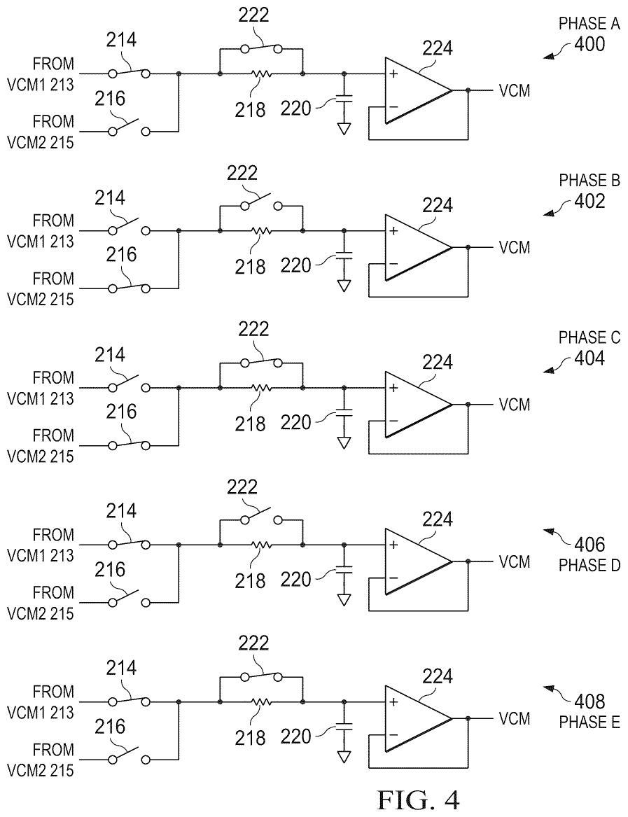

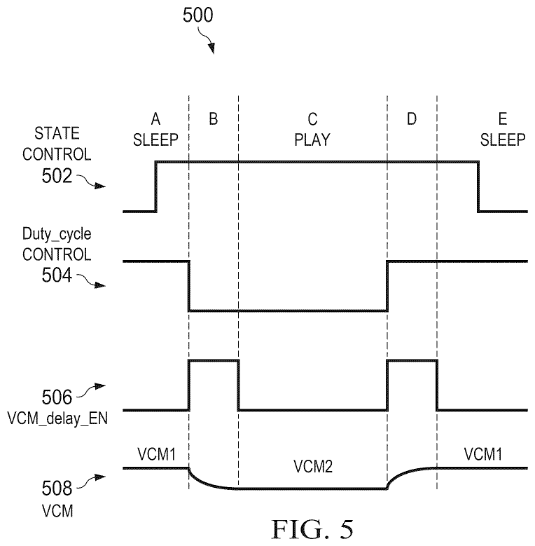

The VCM delay controller 226 of FIG. 2 includes three inputs and three outputs. The first input of the VCM delay controller 226 is coupled to the controller circuitry 228 to receive a state control signal. The second input of the VCM delay controller 226 is coupled to the controller circuitry 228 to receive a duty cycle control signal. The third input of the VCM delay controller 226 is coupled to the clock generation circuitry 110 to receive a clock signal. The first output is coupled to the control terminal of the switch 214 to control the switch 214. The second output of the VCM delay controller 226 is coupled to the control terminal of the switch 216 to control the switch 216. The third output of the VCM delay controller 226 is coupled to the control terminal of the switch 222 to control the switch 222. The VCM delay controller 226 controls the switches 214, 216, 222 responsive to one or both of a state control change or a duty cycle control change. For example, in response to a state change or a duty cycle control change, the VCM delay controller 226 provides control signals to the switches 214, 216, 222 to transition from using the first voltage source 213 to charge the capacitor 220 to using a second voltage source to charge the capacitor 220. A state change may be a change from sleep to play, low power to play, play to sleep, play to lower power, etc. The order of control is further described below in conjunction with FIG. 4. The VCM delay controller 226 may be implemented by any combination of hardware, software, or firmware. A hardware-based implementation of the VCM delay controller 226 is further described below in conjunction with FIG. 5.

The example controller circuitry 228 of FIG. 2 includes a first terminal and a second terminal. The first and second terminals of the controller circuitry 228 are coupled to the VCM delay controller 226. The controller circuitry 228 can implement firmware to control or manage operation of the amplifier 108. For example, the controller circuitry 228 can provide a state control signal that identifies when a state change is to occur. Also, the controller circuitry 228 can provide a duty cycle control signal that identifies when a change in duty cycle control is to occur. As described above, one or both of the state control signal or the duty cycle control signal can trigger the VCM delay controller 226 to adjust the VCM voltage applied to the VCM terminal of the modulator 206 from a first voltage to a second voltage. Changing the VCM voltage from the first voltage to the second voltage adjusts the duty cycle of the amplifier 108 from a first duty cycle to a second duty cycle.

FIG. 3 is a circuit diagram of an example of the modulator 206 of FIG. 2. The modulator 206 includes example fully differential amplifiers 300, 306, example resistors 302, 304, and example capacitors 308, 310, 312, 314, 316, 318. Although FIG. 3 illustrates a fully differential structure, FIG. 3 can be implemented in a single ended system.

The first fully differential amplifier 300 of FIG. 3 includes two inputs and two outputs. The first input of the fully differential amplifier 300 is the inverting input. The first input of the differential amplifier 300 is coupled to the second terminal of the capacitor 312, the second terminal of the resistor 202a, and the second terminal of the resistor 204a. The second input of the fully differential amplifier 300 is a non-inverting input. The second input of the fully differential amplifier 300 is coupled to the second terminal of the capacitor 318, the second terminal of the resistor 202b, and the second terminal of the resistor 204b. The first output of the fully differential amplifier 300 is a non-inverting output. The first output of the fully differential amplifier 300 is coupled to the first terminal of the capacitor 312, the first terminal of the resistor 302, and the second terminal of the capacitor 310. The second output of the fully differential amplifier 300 is an inverting output. The second output of the fully differential amplifier 300 is coupled to the first terminal of the capacitor 318, the first terminal of the resistor 304, and the second terminal of the capacitor 316.

The resistors 302, 304 of FIG. 3 each include a first terminal and a second terminal. The first terminal of the resistor 302 is coupled to the first output of the fully differential amplifier 300, the first terminal of the capacitor 312, and the second terminal of the capacitor 310. The first terminal of the resistor 302 is coupled to the second output of the fully differential amplifier 300, the first terminal of the capacitor 318, and the second terminal of the capacitor 316. The second terminal of the resistor 302 is coupled to the first input of the amplifier 306, the second terminal of the capacitor 308, and the first terminal of the capacitor 310. The second terminal of the resistor 302 is coupled to the second input of the amplifier 306, the second terminal of the capacitor 314, and the first terminal of the capacitor 316.

The second fully differential amplifier 306 of FIG. 3 includes three inputs and two outputs. The first input of the fully differential amplifier 306 is an inverting input. The first input of the fully differential amplifier 306 is coupled to the second terminal of the capacitor 308, the second terminal of the resistor 302, and the first terminal of the capacitor 310. The second input of the fully differential amplifier 306 is a non-inverting input. The second input of the fully differential amplifier 306 is coupled to the second terminal of the capacitor 314, the second terminal of the resistor 304, and the first terminal of the capacitor 316. The VCM input of the fully differential amplifier 306 is coupled to the output of the buffer 224 of FIG. 2. The first output of the fully differential amplifier 306 is a non-inverting output. The first output of the fully differential amplifier 306 is coupled to the first terminal of the capacitor 308 and the comparator 208a of FIG. 2. The second output of the fully differential amplifier 306 is an inverting output. The second output of the fully differential amplifier 306 is coupled to the first terminal of the capacitor 314 and the comparator 208b of FIG. 2.

The capacitors 308, 310, 312, 314, 316, 318 of FIG. 3 each include two terminals. The first terminal of the capacitor 308 is coupled to the first output of the amplifier 306 and the comparator 208a of FIG. 2. The first terminal of the capacitor 310 is coupled to the second terminal of the capacitor 308, the second terminal of the resistor 302, and the first input of the amplifier 306. The first terminal of the capacitor 312 is coupled to the first output of the amplifier 300, the first terminal of the resistor 302, and the second terminal of the capacitor 310. The first terminal of the capacitor 314 is coupled to the second output of the amplifier 306 and the comparator 208a of FIG. 2. The first terminal of the capacitor 316 is coupled to the second terminal of the capacitor 314, the second terminal of the resistor 304, and the second input of the amplifier 306. The first terminal of the capacitor 318 is coupled to the second output of the amplifier 300, the first terminal of the resistor 304, and the second terminal of the capacitor 316. The second terminal of the capacitor 308 is coupled to the first terminal of the capacitor 310, the second terminal of the resistor 302, and the first input of the amplifier 306. The second terminal of the capacitor 310 is coupled to the first terminal of the capacitor 312, the first output of the amplifier 300 and the first terminal of the resistor 302. The second terminal of the capacitor 312 is coupled to the resistors 202a, 204a and the first input of the amplifier 300. The second terminal of the capacitor 314 is coupled to the first terminal of the capacitor 316, the second terminal of the resistor 304, and the second input of the amplifier 306. The second terminal of the capacitor 316 is coupled to the first terminal of the capacitor 318, the second output of the amplifier 300 and the first terminal of the resistor 304. The second terminal of the capacitor 318 is coupled to the resistors 202a, 204a and the second input of the amplifier 300.

As described above, the modulator 206 uses the differential amplifier(s) 300, 306, resistors 302, 304, and capacitor(s) 308, 310, 312, 314, 316, 318 to integrate the output stage differential output signals with the input differential analog audio signals forming a closed loop to remove or reduce errors in the output signal(s). The modulator 206 provides the differential output signals that correspond to the integrated output stage differential to the output signals of the driver circuitries 210a, 210b.

FIG. 4 illustrates different phases of control of the switches 214, 216, 222 during a first state change and a second state change. The first state change may correspond to a state change from phase a to phase c, for example. The second state change may correspond to a stage change from phase c to phase e, for example. FIG. 4 includes example phases 400, 402, 404, 406, 408. FIG. 4 further includes the voltage sources 213, 215, the switches 214, 216, 222, the resistor 218, the capacitor 220, and the buffer 224 of FIG. 2. In FIG. 4, phase a is a first phase, phase b is a second phase, phase c is a third phase, phase d is a fourth phase, and phase 3 is a fifth phase.

The first phase 400 of FIG. 4 corresponds to a low power state/mode, sleep state/mode, off state/mode, etc. In the first phase 400, the VCM delay controller 226 provides control signals to close the switches 214, 222 and open the switch 216. In this manner, the first voltage source VCM1 213 is applied to the capacitor 220. Thus, the voltage at the first input of the buffer 224 is equal to VCM1. Because the buffer 224 provides the voltage at the first input to the VCM terminal of the modulator 206, the buffer 224 provides the VCM1 voltage to the VCM terminal of the modulator 206. Thus, the amplifier 108 starts a duty cycle signal at a first duty cycle, for example less than a 10 % duty cycle. At the second phase 402, after a state change, the VCM delay controller 226 provides control signals to close the switch 216, and open switches 214, 222. Thus, the second voltage source 215 is coupled to the resistor 218 to cause the capacitor 220 to discharge from the VCM1 voltage toward the VCM2 voltage. Thus, the voltage at the first input of the buffer 224 decreases exponentially toward the VCM2 voltage. Accordingly, the duty cycle increases logarithmically from the first duty cycle to a second duty cycle, for example 50%. At the third phase 404, the VCM duty controller 226 provides control signals to open the switch 214 and close the switches 216, 222. This causes the voltage at the first input of the buffer 224 to settle to the VCM2 voltage, thereby causing the duty cycle to settle at the second duty cycle. Also, shorting the resistor 218 prevents leakage through the resistor 218.

After a state change back to sleep mode/state from the play mode/state, the third phase 404 of FIG. 4 transitions to the fourth phase 406. At the fourth phase 406, the VCM delay controller 226 provides control signals to close the switch 214 and open the switches 216. Thus, the first voltage source 213 is coupled to the resistor 218 to cause the capacitor 220 to charge from the VCM2 voltage toward the VCM1 voltage. Thus, the voltage at the first input of the buffer 224 increases logarithmically toward the VCM1 voltage. Accordingly, the duty cycle decreases exponentially from the second duty cycle to the first duty cycle, for example a less than 10% duty cycle. At the fifth phase 408, the VCM duty controller 226 provides control signals to open the switch 216 and close the switches 214, 222. This causes the voltage at the first input of the buffer 224 to settle to the VCM1 voltage, thereby causing the duty cycle to settle at the first duty cycle. Also, shorting the resistor 218 prevents leakage through the resistor 218.

FIG. 5 is an example timing diagram 500 that illustrates voltage signals 502, 504, 506, 508 that correspond to different nodes in the amplifier 108 of FIG. 2. The first voltage signal 502 is a state control signal corresponding to the voltage at the state control terminal of the controller circuitry 228. The second voltage signal 504 is a duty cycle control signal corresponding to the voltage at the duty cycle control terminal of the controller circuitry 228. The third voltage 506 is a the VCM delay enable signal corresponding to the voltage output to the control terminal of the switch 222. The fourth voltage 508 is a the VCM signal corresponding to the voltage output by the buffer 224 to the VCM terminal of the modulator 206.

The timing diagram 500 of FIG. 5 starts with the amplifier 108 operating in a sleep mode. Responsive to the first voltage signal 502 transitioning from a sleep state mode to a play state mode by transitioning to a logic high voltage and the second voltage signal 504 transitioning to a logic low voltage, the VCM delay controller 226 opens the switches 214, 222 and closes the switch 216, thereby causing the voltage signal 506 to exponentially decrease from the VCM1 voltage to the VCM2 voltage. After a threshold amount of time, the third voltage signal 506 decreases to a logic low voltage, thereby closing the switch 222 and causing the fourth voltage signal 508 to settle at the VCM2 voltage.

Responsive to the first voltage signal 502 of FIG. 5 transitioning to a logic low voltage and the second voltage signal 504 transitioning to a logic high voltage to transition from the play state to the sleep state, the VCM delay controller 226 opens the switches 216, 222 and closes the switch 214, thereby causing the voltage signal 506 to logarithmically increase from the VCM2 voltage to the VCM1 voltage. After a threshold amount of time, the third voltage signal 506 decreases to a logic low voltage, thereby closing the switch 222 and causing the fourth voltage signal 508 to settle at the VCM1 voltage.

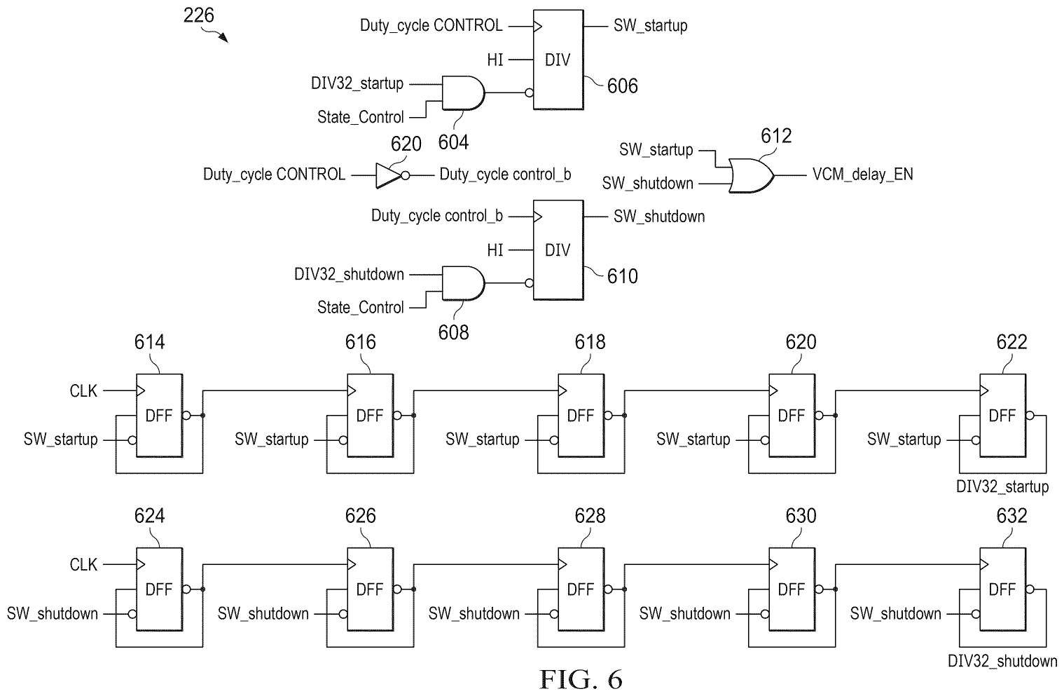

FIG. 6 illustrates an example hardware implementation of the VCM delay controller 226 of FIG. 2. FIG. 6 includes example logic gates 602, 604, 608, 612, and example flip flops 606, 610, 614, 616, 618, 620, 622, 624, 626, 628, 630, 632. Although FIG. 6 illustrates an example hardware implementation of the VCM delay controller 226. There may be alternative ways to implement the VCM delay controller 226 to control the switches 214, 216, 222 of FIG. 2 based on the phases described in FIG. 4.

The logic gate 602 of FIG. 6 is a logic not gate (also referred to as an inverter). The logic gate 602 includes an input and an output. The input of the logic gate 602 is coupled to the controller circuitry 228 of FIG. 2 to receive the duty cycle control signal (e.g., signal 504 of FIG. 5) and an input of the flip flop 606. The output of the logic gate 602 is coupled to an input of the flip flop 610. The logic gate 602 inverts the duty cycle control signal. For example, if the duty cycle control signal is a logic low voltage, the logic gate 602 provides a logic high voltage. If the duty cycle control signal is a logic high voltage, the logic gate 602 provides a logic low voltage. Accordingly, because the duty cycle control b signal is at the output of the logic gate 602, the duty control b signal is the opposite of the duty control signal, for example when the duty control signal is high, the duty control b signal is low and vice versa.

The logic gate 604 of FIG. 6 is a logic AND gate. The logic gate 604 includes a first input, a second input, and an output. The first input of the logic gate 604 is coupled to the flip flop 622 to receive the DIV32 startup signal. The second terminal of the logic gate 604 is coupled to the controller circuitry 228 of FIG. 2 to receive the state control signal (e.g., signal 502 of FIG. 5). The output of the logic gate 604 is coupled to the flip flop 606. The logic gate 604 provides a logic high voltage when the voltages at both inputs correspond to logic high voltages. Otherwise, the logic gate 604 provides a logic low voltage.

The flip flop 606 of FIG. 6 is a D-type flip flop. The flip flop 606 includes three inputs and an output. The first input is a clock input that is coupled to the controller circuitry 228 of FIG. 2 and the input of the logic gate 602 to receive the duty cycle control signal. The second terminal of the flip flop 606 is coupled to a voltage source that generates a logic high voltage (e.g., a voltage source). The third input of the flip flop 606 is an inverted input that is coupled to the output of the logic gate 604. The output of the flip flop 606 is coupled to the logic gate 612 and the flip flops 614, 616, 618, 620, 622 to provide the SW startup signal. The flip flop 606 generates a logic high pulse at the output of the flip flop 606 when the state control and duty cycle control transitions from a first state to a second state. The output of logic gate 604 operates a reset signal of the flip flop 606. Also, DIV32_startup is logic high by default. When the state control is logic low, the flip flop 606 is in a reset state. After the state control changes to logic high, the flip flop 606 starts functioning. When the duty cycle control signal rises from a logic low to a logic high, the SW startup output signal becomes logic high, which triggers the logic gate 612 to provide a logic high at the VCM_delay_EN terminal. As further described below, a logic high at the SW startup terminal causes then the flip-flops 614, 616, 618, 620, and 622 to operate. DIV32_startup changes to a logic low after some delay time, thereby causing the flip flop 606 to reenter a reset state and causing the SW startup output signal to return to a logic low.

The logic gate 608 of FIG. 6 is a logic AND gate. The logic gate 608 includes a first input, a second input, and an output. The first input of the logic gate 608 is coupled to the flip flop 632 to receive the DIV32 shutdown signal. The second terminal of the logic gate 608 is coupled to the controller circuitry 228 of FIG. 2 to receive the state control signal (e.g., signal 502 of FIG. 5). The output of the logic gate 608 is coupled to the flip flop 610. The logic gate 608 provides (e.g., outputs) a logic high voltage when the voltages at both inputs correspond to logic high voltages. Otherwise, the logic gate 608 provides a logic low voltage.

The flip flop 610 of FIG. 6 is a D-type flip flop. The flip flop 610 holds the output signal until a subsequent rising edge or falling edge of the input signal is detected and the process repeats. The flip flop 610 includes three inputs and an output. The first input is the clock input that is coupled to the output of the logic gate 602 to receive a duty cycle control b signal. The b signal is the invert of the duty cycle control signal. The second terminal of the flip flop 610 is coupled to a voltage source that generates a logic high voltage (e.g., a voltage source). The third input of the flip flop 610 is an inverted input that is coupled to the output of the logic gate 608. The output of the flip flop 610 is coupled to the logic gate 612 and the flip flops 624, 626, 628, 630, 632 to provide the DIV32 shutdown signal. The output signal of logic gate 608 operates a reset signal of the flip flop 610. Also, the DIV32_shudown signal is logic high by default. When the state control signal is logic low, the flip flop 606 is in a reset state. After the state control changes to logic “high,” the flip flop 610 starts functioning. When the duty cycle control signal falls from a logic high to a logic low, the duty_cycle_control_b rises due to the logic gate 602. Thus, the SW shutdown output signal becomes a logic “high,” which triggers the logic gate 612 to provide a logic high at the VCM_delay_EN terminal. As further described below, a logic high at the SW shutdown terminal causes the flip-flops 624, 626, 628, 630, and 632 to operate. DIV32_shutdown changes to logic low after some delay time, thereby causing the flip flop 610 to reenter the reset state again and causing the SW shutdown output signal to return to a logic low.

The logic gate 612 of FIG. 6 is a logic OR gate. The logic gate 612 includes a first input, a second input, and an output. The first input of the logic gate 612 is coupled to the flip flops 614, 616, 618, 620, 622 and the output of the flip flop 606 to receive a SW_startup signal. The second input of the logic gate 612 is coupled to the flip flops 624, 626, 628, 630, 632 and the output of the flip flop 610 to receive the SW_shutdown signal. The output of the logic gate 612 is coupled to the control terminal of the switch 222 of FIG. 2 to control the switch 222. The logic gate 612 provides a logic high voltage if either one of the SW_startup signal or the SW_shutdown signal is high. If both the SW_startup signal and the SW_shutdown signal are low, the logic gate 612 provides a logic low volage.

The flip flops 614, 616, 618, 620, 622 of FIG. 6 generate the DIV32_startup signal based on the SW_startup signal and a clock signal. The DIV32_startup signal is a logic high voltage until the SW_startup signal decreases to a low signal. When the SW_startup signal decreases to a low signal, the DIV_startup signal pulse to a logic low signal. The flip flops 614, 616, 618, 620, 622 each include three inputs and an output. The first input is an input clock terminal of the flip flop 614 that is coupled to the clock generation circuitry 110 of FIG. 1 to receive a clock signal. The first inputs are clock inputs of the flip flops 616, 618, 620, 622 that are coupled to the output of a previous flip flop in the system, for example one or the flip flops 614, 616, 618, 620). The second inputs are the first inverted inputs of the flip flops 614, 616, 618, 620, 622 that are coupled to the output of the flip flop 606 and the first input of the logic gate 612 to receive the SW_startup signal. Each of the third inputs of the flip flops 614, 616, 618, 620, 622 are coupled to the output of corresponding flip flop 614, 616, 618, 620 622 and the clock input of a subsequent flip flop 616, 618, 620, 622. For example, the third input of the flip flop 614 is coupled to the output of the flip flop 614 and the clock input of the flip flop 616. Each of the outputs of the flip flops 614, 616, 618, 620, 622 are coupled to the third input of the corresponding flip flop 614, 616, 618, 620, 622 and the clock input of a subsequent flip flop 616, 618, 620, 622. The output of the flip flop 622 corresponds to the DIV32_startup terminal that is coupled to the first input of the logic gate 604.

The flip flops 624, 626, 628, 630, 632 of FIG. 6 generate the DIV32_shutdown signal based on the SW_shutdown signal and a clock signal. The DIV32_shutdown signal is a logic high voltage until the SW_shutdown signal decreases to a low signal. When the SW_shutdown signal decreases to a low signal, the DIV_startup signal pulse to a logic low signal. The flip flops 624, 626, 628, 630, 632 each include three inputs and an output. The first input is an input clock terminal of the flip flop 624 that is coupled to the clock generation circuitry 110 of FIG. 1 to receive a clock signal. The first inputs are clock inputs of the flip flops 626, 628, 630, 632 that are coupled to the output of a previous flip flop in the system, for example one or the flip flops 624, 626, 628, 630. The second inputs are first inverted inputs of the flip flops 624, 626, 628, 630, 632 that are coupled to the output of the flip flop 606 and the first input of the logic gate 612 to receive the SW_shutdown signal. Each of the third inputs are second inverted inputs of the flip flops 624, 626, 628, 630, 632 that are coupled to the output of corresponding flip flop 624, 626, 628, 630 632 and the clock input of a subsequent flip flop 626, 628, 630, 632. For example, the third input of the flip flop 624 is coupled to the output of the flip flop 624 and the clock input of the flip flop 626. Each of the outputs of the flip flops 624, 626, 628, 630, 632 are coupled to the third input of the corresponding flip flop 624, 626, 628, 630, 632 and the clock input of a subsequent flip flop 626, 628, 630, 632. The output of the flip flop 632 corresponds to the DIV32_shutdown terminal that is coupled to the first input of the logic gate 608.

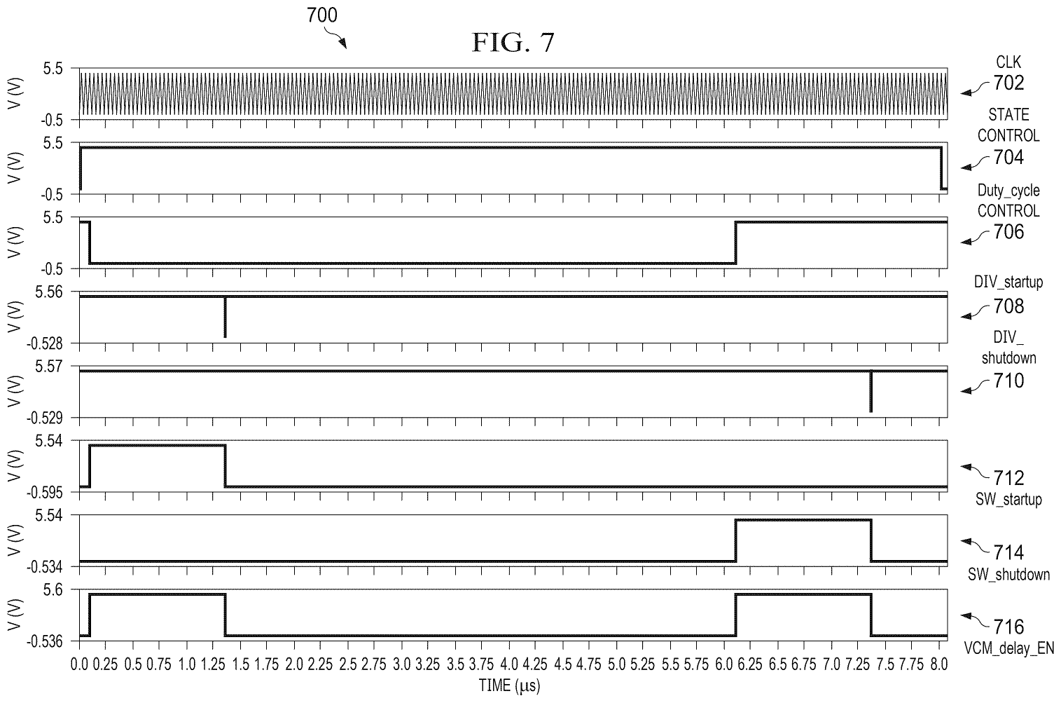

FIG. 7 is an example timing diagram 700 that illustrates voltage signals 702, 704, 706, 708, 710, 712, 714, 716 that correspond to different nodes in the circuity implementation of the VCM delay controller 226 of FIG. 6. The first voltage signal 702 is a CLK signal corresponding to the voltage output by the clock generation circuitry 110 and received at the clock input of the flip flops 614, 624. The second voltage signal 704 is a state control signal corresponding to the voltage output by the controller circuitry 228 and received at the second inputs of the logic gates 604, 608. The third voltage 706 is a duty cycle control signal corresponding to the voltage output by the controller circuitry 228 and received at the clock input of the flip flops 606, 610. The fourth voltage 708 is a DIV startup signal or a DIV32 startup signal corresponding to the voltage output at the output of the flip flop 622 and the first input of the logic gate 604. The fifth voltage 710 is a DIV shutdown or a DIV32 shutdown signal corresponding to the voltage output at the output of the flip flop 632 and the first input of the logic gate 608. The sixth voltage 712 is a SW startup signal corresponding to the voltage output by the flip flop 606 and received at the second inputs of the flip flops 614, 616, 618, 620, 622. The seventh voltage 714 is a SW shutdown signal corresponding to the voltage output by the flip flop 610 and received at the second inputs of the flip flops 624, 626, 628, 630, 632. The eight voltage 716 is a VCM delay enable signal corresponding to the voltage output by the logic gate 612 and is applied to the control terminal of the switch 222 of FIG. 2.

After the clock control voltage 704 increases to a high voltage and the duty cycle control voltage 706 decreases to a low voltage, the flip flop 606 adjusts the SW startup voltage 712 from a logic low voltage to a logic high voltage. Because the SW startup voltage 712 is high, the output signal of the logic gate 612 raises to a logic high voltage, as shown in the VCM delay enable voltage 716. The flip flop 606 holds the high voltage for the SW startup voltage 712 until the DIV_startup voltage 708 pulses low. After the DIV_startup voltage 708 pulses low, the flip flop 606 decreases the SW startup voltage 712 to a logic low voltage.

After the duty cycle control voltage 706 raises back to a logic high voltage, the flip flop 610 increases the SW shutdown voltage 714 to a logic high voltage. Because the SW shutdown voltage 714 is high, the output signal of the logic gate 612 raises to a logic high voltage, as shown in the VCM delay enable voltage 716. The flip flop 610 holds the high voltage for the SW shutdown voltage 714 until the DIV_shutdown voltage 710 pulses low. After the DIV_shutdown voltage 710 pulses low, the flip flop 610 decreases the SW_shutdown voltage 714 to a logic low voltage.

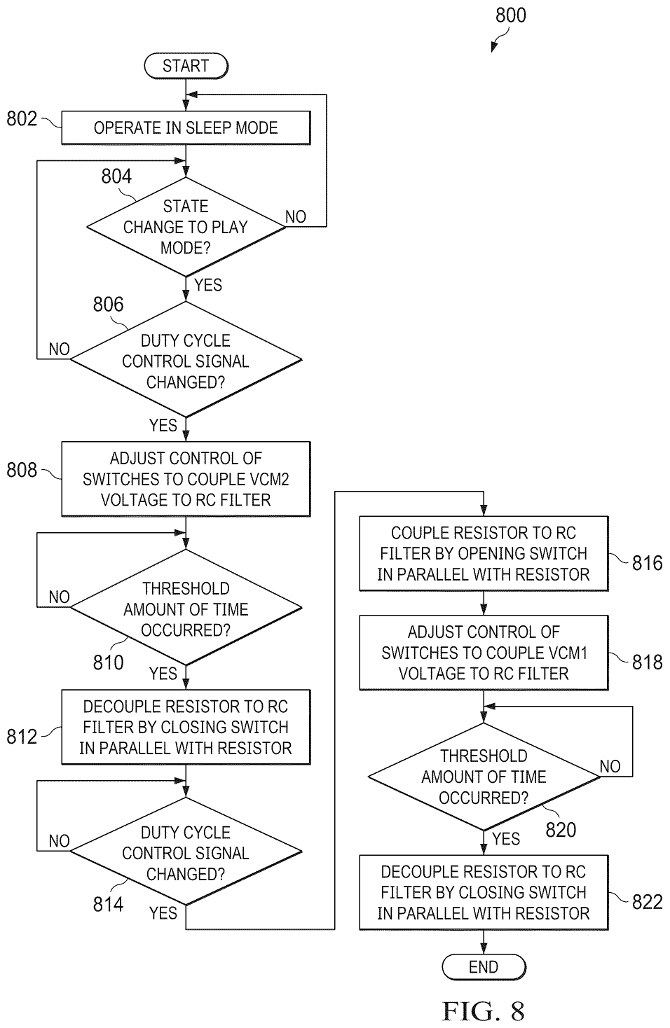

FIG. 8 is a flowchart representative of example machine readable instructions or example operations 800 that may be executed, instantiated, or performed by programmable circuitry to control the switches 214, 216, 222 of FIG. 2 to reduce pops or clicks during a state or mode transition. The example machine-readable instructions or the example operations 800 of FIG. 8 begin at block 802, at which the VCM delay controller 226 is controlling the switches 214, 216, 222 to operate in sleep, off, or low power mode. For example, during sleep mode, the VCM delay controller 226 closes the switches 214, 222 and opens the switch 216.

At block 804, the VCM delay controller 226 determines if a state change to play mode has occurred. For example, the VCM delay controller 226 receives a state control signal from the control circuitry 228 of FIG. 2 that indicates whether a state change has occurred. If the VCM delay controller 226 determines that a state change to play mode has not occurred (block 804: NO), control returns to block 802. If the VCM delay controller 226 determines that a state change to play mode has occurred (block 804: YES), the VCM delay controller 226 determines if a duty cycle control signal has changed (block 806), for example, from a logic high voltage to a logic low voltage). The duty cycle control signal is a signal received from the controller circuitry 228 to indicate that the duty cycle changes based on the state change.

If the VCM delay controller 226 determines that the duty cycle control signal has not changed (block 806: NO), control returns to block 804. If the VCM delay controller 226 determines that the duty cycle control signal has changed (block 806: YES), the VCM delay controller 226 adjusts the control of the VCM switches to couple the VCM2 voltage to the RC filter (block 808). For example, the VCM delay controller 226 opens the switch 214 to decouple the first voltage source 213, closes the switch 216 and opens the switch 222 to couple the second voltage source 215 to the resistor 218 and capacitor 220 that make up filter circuitry. At block 810, the VCM delay controller 226 determines if a threshold amount of time has occurred. The threshold amount of time may correspond to the capacitance and resistance of the filter circuitry. If the VCM delay controller 226 determines that the threshold amount of time has not occurred (block 810: NO), control returns to block 810. If the VCM delay controller 226 determines that the threshold amount of time has occurred (block 810: YES), the VCM delay controller 226 decouples the resistor 218 from the filtering circuitry by closing the switch 222 in parallel with the resistor 218 (block 812). By closing the switch 222, the VCM delay controller 226 shorts the terminals of the resistor 218, thereby causing the voltage output by the buffer 224 to stabilize to the VCM2 voltage.

At block 814, the VCM delay controller 226 determines if a duty cycle control signal has changed, for example, from a logic low voltage to a logic high voltage. If the VCM delay controller 226 determines that the duty cycle control signal has not changed (block 814: NO), control returns to block 814. If the VCM delay controller 226 determines that the duty cycle control signal has changed (block 814: YES), the VCM delay controller 226 couples the resistor 218 to the filter circuitry by opening the switch 222 that is parallel to the resistor 218 (block 816). At block 818, the VCM delay controller 226 adjusts the control of the VCM switches to couple the VCM1 voltage to the RC filter. For example, the VCM delay controller 226 closes the switch 214 to couple the first voltage source 213 to the resistor 218 and opens the switch 216 to decouple the second voltage source 215 from the resistor 218. At block 820, the VCM delay controller 226 determines if a threshold amount of time has occurred. The threshold amount of time may correspond to the capacitance and resistance of the filter circuitry. If the VCM delay controller 226 determines that the threshold amount of time has not occurred (block 820: NO), control returns to block 820. If the VCM delay controller 226 determines that the threshold amount of time has occurred (block 820: YES), the VCM delay controller 226 decouples the resistor 218 from the filtering circuitry by closing the switch 222 in parallel with the resistor 218 (block 822). By closing the switch 222, the VCM delay controller 226 shorts the terminals of the resistor 218, thereby causing the voltage provided by the buffer 224 to stabilize to the VCM1 voltage.

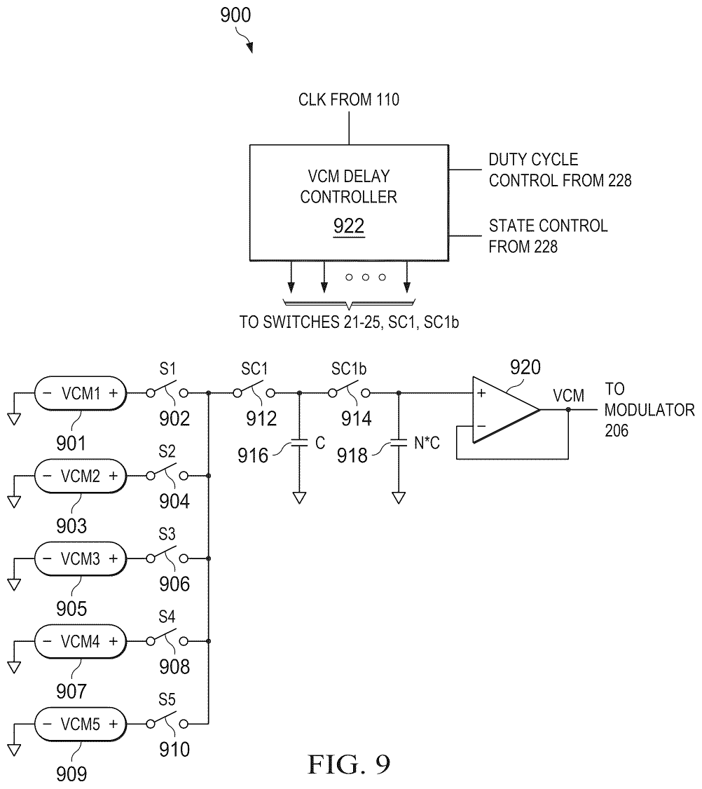

FIG. 9 illustrates example common mode voltage generation circuitry 900 which is an alternative implementation of the common mode voltage generation circuitry 212 of FIG. 2. The common mode voltage generation circuitry 900 of FIG. 9 includes example voltage sources 901, 903, 905, 907, 909, example switches 902, 904, 906, 908, 910, 912, 914, example capacitors 916, 918, an example buffer 920, and an example VCM delay controller 922. Although the example of FIG. 9 includes 5 voltage sources coupled to 5 switches, there may be any number of voltage sources or switches. Rather than the filtering circuitry of FIG. 2, which including the resistor 218, the capacitor 220, and the switch 222, the filtering circuitry of FIG. 9 includes a switching capacitor configuration that includes the switches 912, 914 and the capacitors 916, 918. The switched capacitor configuration simulates a resistor. Accordingly, both the filtering circuitry of FIG. 2 and the filtering circuitry of FIG. 9 operate as an RC filter to provide a non-linear adjustment of VCM voltage to adjust the duty cycle. The switch 902 corresponds to switch S1, the switch 904 corresponds to switch S2, the switch 906 corresponds to switch S3, the switch 908 corresponds to switch S4, the switch 910 corresponds to switch S5, the switch 912 corresponds to switch SC1, and the switch 914 corresponds to switch SC1b, The voltage sources 901, 903, 905, 907, 909 of FIG. 2 each include a terminal. The terminal of the voltage source 901 is coupled to a first terminal of the switch 902. The terminal of the voltage source 903 is coupled to a first terminal of the switch 904. The terminal of the voltage source 905 is coupled to a first terminal of the switch 906. The terminal of the voltage source 907 is coupled to a first terminal of the switch 908. The terminal of the voltage source 909 is coupled to a first terminal of the switch 910. The voltage sources 901, 903, 905, 907, 909 each provide a particular voltage. The voltage generated by the voltage sources 901, 903, 905, 907, 909 is a common mode voltage that is eventually applied to common mode terminal of the modulator 206 via filtering circuitry, including the switches 912, 914 and capacitors 916, 918. The common mode voltage corresponds to a particular duty cycle. For example, the first voltage source 901 may provide a voltage that corresponds to a low duty cycle (e.g., 10%), the second voltage source 903 may provide a voltage that corresponds to a slightly higher duty cycle (e.g., 20%), . . . and the fifth voltage source 909 may provide a voltage that corresponds to a high duty cycle (e.g., 50%).

The switches 902, 904, 906, 908, 910 of FIG. 2 each include a first terminal, a second terminal, and a control terminal. The first terminal of the switch 902 is coupled to the first voltage source 901. The first terminal of the switch 904 is coupled to the second voltage source 903. The first terminal of the switch 906 is coupled to the third voltage source 905. The first terminal of the switch 908 is coupled to the fourth voltage source 907. The first terminal of the switch 910 is coupled to the fifth voltage source 909. The first terminal of the switch 912 is coupled to the second terminals of the switches 902, 904, 906, 908, 910. The first terminal of the switch 914 is coupled to the second terminal of the switch 912 and the first terminal of the capacitor 916. The first terminals of the switches 902, 904, 906, 908, 910 are also referred to as voltage source terminals. The second terminal of the switch 902 is coupled to the second terminals of the switches 904, 906, 908, 910, and the first terminal of the switch 912. The second terminal of the switch 904 is coupled to the second terminals of the switches 902, 906, 908, 910, and the first terminal of the switch 912. The second terminal of the switch 906 is coupled to the second terminals of the switches 902, 904, 908, 910, and the first terminal of the switch 912. The second terminal of the switch 908 is coupled to the second terminals of the switches 902, 904, 906, 910, and the first terminal of the switch 912. The second terminal of the switch 910 is coupled to the second terminals of the switches 902, 904, 906, 908, and the first terminal of the switch 912. The second terminal of the switch 912 is coupled to the first termina of the switch 914 and the first terminal of the capacitor 916. The control terminals of the switches 902, 904, 906, 908, 910, 912, 914 are each coupled to the VCM delay controller 922. The switches 902, 904, 906, 908, 910, 912, 914 can individually controlled to operate as an open connection or a closed connection, as further described below. The switches 902, 904, 906, 908, 910, 912, 914 may be implemented by transistors, such as field effect transistors.

The capacitors 916, 918 of FIG. 9 each includes a first terminal and a second terminal. The first terminal of the capacitor 916 is coupled to the second terminal of the switch 912 and the first terminal of the switch 914. The first terminal of the capacitor 918 is coupled to the second terminal of the switch 914 and the first input of the buffer 920. The second terminals of the capacitors 916, 918 are coupled to a common terminal (e.g., a ground terminal). When the switch 912 is closed and switch 914 is open, the capacitor 916 stores charge from the voltage source, for example, based on which one of the switches 902, 904, 906, 908, 910 is closed. When the switch 912 is open and the switch 914 is closed, the capacitor 916 discharges to charge the capacitor 918. The charge stored in the capacitor 918 creates a voltage at the first terminal of the buffer 920, which is provided to the common mode terminal of the modulator 206.

The buffer 920 of FIG. 9 includes a first input, a second input, and an output. The first input of the buffer 920 is a non-inverting terminal. The first input of the buffer 920 is coupled to the second terminal of the switch 914 the first terminal of the capacitor 918. The second input of the buffer 920 is an inverting terminal. The second input of the buffer 920 is coupled to the output of the buffer 920 and the VCM terminal of the modulator 206. The output of the buffer 920 is coupled to the second input of the buffer 920 and the VCM terminal of the modulator 206. The buffer 920 provides the voltage at the first input of the buffer 920 to the modulator 206 without drawing current from the capacitor 916.

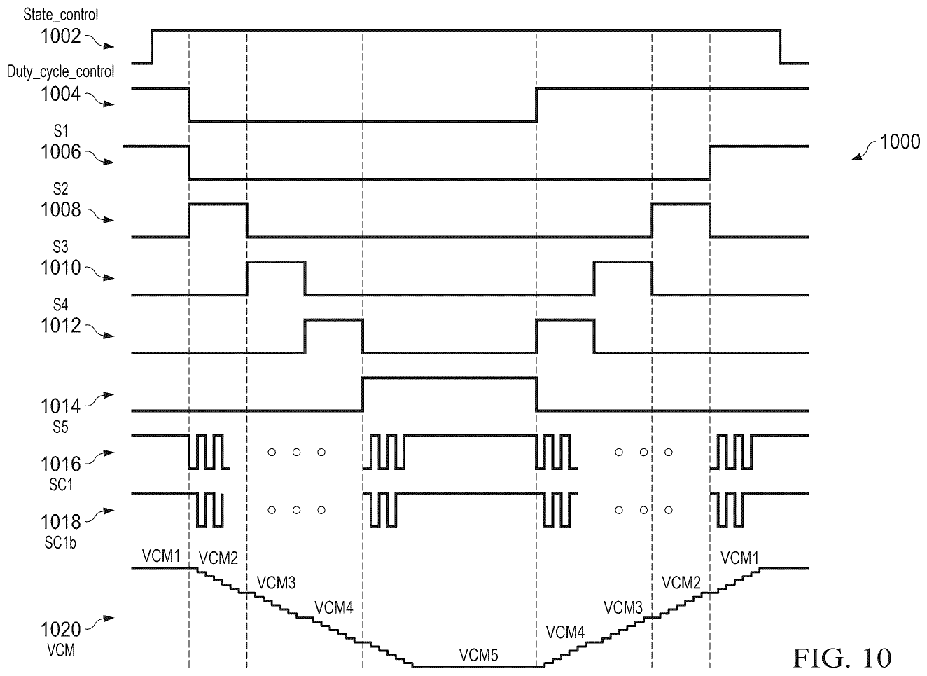

The VCM delay controller 922 of FIG. 2 includes three inputs and multiple outputs. The first input of the VCM delay controller 922 is coupled to the controller circuitry 228 to receive a state control signal. The second input of the VCM delay controller 922 is coupled to the controller circuitry 228 to receive a duty cycle control signal. The third input of the VCM delay controller 922 is coupled to the clock generation circuitry 110 to receive a clock signal. The outputs of the VCM delay controller 922 are coupled to respective control terminals of the switches 902, 904, 906, 908, 910, 912, 914. The VCM delay controller 922 controls the switches 902, 904, 906, 908, 910, 912, 914 based on at least one of a state control change or a duty cycle control change. For example, in response to at least one of a state change or a duty cycle control change, the VCM delay controller 922 toggles the switches 912, 914 on and off, for example, when the switch 912 is open the switch 914 is closed and vice versa. Also, the VCM delay controller 922 provides control signals to the switches 902, 904, 906, 908, 910 to transition from using the first voltage source 901 to charge the capacitor(s) 916, 918 to using a second voltage source to charge the capacitor(s) 916, 918. The control of the switches 902, 904, 906, 908, 910, 912, 914 in conjunction with the capacitors 916, 918 is further described below in conjunction with FIGS. 10-13. The VCM delay controller 922 may be implemented by any combination of hardware, software, or firmware.

FIG. 10 illustrates a timing diagram 1000 including example signals 1002, 1004, 1006, 1008, 1010, 1012, 1014, 1016, 1020. The voltage signal 1002 is a state control signal corresponding to the voltage output by the controller circuitry 228 of FIG. 2. The voltage signal 1004 is a duty cycle control signal corresponding to the voltage output by the controller circuitry 228. The control signal 1006 is an S1 control signal corresponding to the voltage output by the VCM delay controller 922 to the control terminal of the switch 902. The control signal 1008 is an S2 control signal corresponding to the voltage output by the VCM delay controller 922 to the control terminal of the switch 904. The control signal 1010 is an S3 control signal corresponding to the voltage output by the VCM delay controller 922 to the control terminal of the switch 906. The control signal 1012 is an S4 control signal corresponding to the voltage output by the VCM delay controller 922 to the control terminal of the switch 908. The control signal 1014 is an S5 control signal corresponding to the voltage output by the VCM delay controller 922 to the control terminal of the switch 910. The control signal 1016 is an SC1 control signal corresponding to the voltage output by the VCM delay controller 922 to the control terminal of the switch 912. The control signal 1018 is an SC1b control signal corresponding to the voltage output by the VCM delay controller 922 to the control terminal of the switch 914. The voltage signal 1020 is a VCM signal corresponding to the voltage at the output of the buffer 920, which is applied to the common mode voltage terminal of the modulator 206.

When the amplifier 108 is operating in sleep mode, the state control signal 1002 is low, the duty cycle control signal 1004 is high, the first control signal 1006 is high, the control signals 1016, 1018 are high, and the control signals 1008, 1010, 1012, 1014 for the other switches are low. Accordingly, the switches 902, 912, 914 are closed so that the VCM1 voltage source 901 is applied to the input of the buffer 920. Thus, the VCM voltage 1020 remains at the VCM1 voltage corresponding to a first duty cycle (e.g., 10%). When the amplifier 108 enters a play mode, the state control signal 1002 is high, the duty cycle control signal 1004 is low, thereby triggering the VCM delay controller 922 to begin to toggle the switches 912, 914 using the differential pulsing signals 1016, 1018. Also, the VCM delay controller 922 decreases the first control signal 1006 and increase the second control signal 1008 to open the first switch 902 and close the second switch 904, thereby decreasing the voltage applied to the capacitors 916, 918 to the VCM2 voltage. Thus, the VCM voltage 1020 provided by the buffer 920 decreases to the VCM2 voltage, which is applied to the modulator 206 to increase the duty cycle to a second duty cycle (e.g., 20%).

After a duration of time, the VCM delay controller 922 decreases the second control voltage 1008 to a logic low voltage and increases the third control voltage 1010 to a logic high voltage. In this manner, the switch 906 is closed to allow the third voltage source 905 to charge the capacitor 916, 918, thereby decreasing the voltage at the input of the buffer 920 to the VCM3. Thus, the VCM voltage 1020 provided by the buffer 920 decreases to the VCM3 voltage, which is applied to the modulator 206 to increase the duty cycle to a third duty cycle (e.g., 30%). This process continues to enable and disable (close and open or connect and disconnect) switches to decrease the VCM voltage 1020 until the final voltage source 909 is coupled to the filtering circuitry that includes the capacitors 916, 918. When the final voltage source 909 is coupled to the filtering circuitry, the amplifier is operating in play mode with a final duty cycle (e.g., 50%). When the duty cycle control signal 1004 rises back up to a logic high voltage to transition back to sleep or low power mode, the process is repeated in reverse order to increase the VCM voltage 1020 to the VCM1 voltage. Thus, the duty cycle decreases from the 50% duty cycle to a 10% duty cycle.

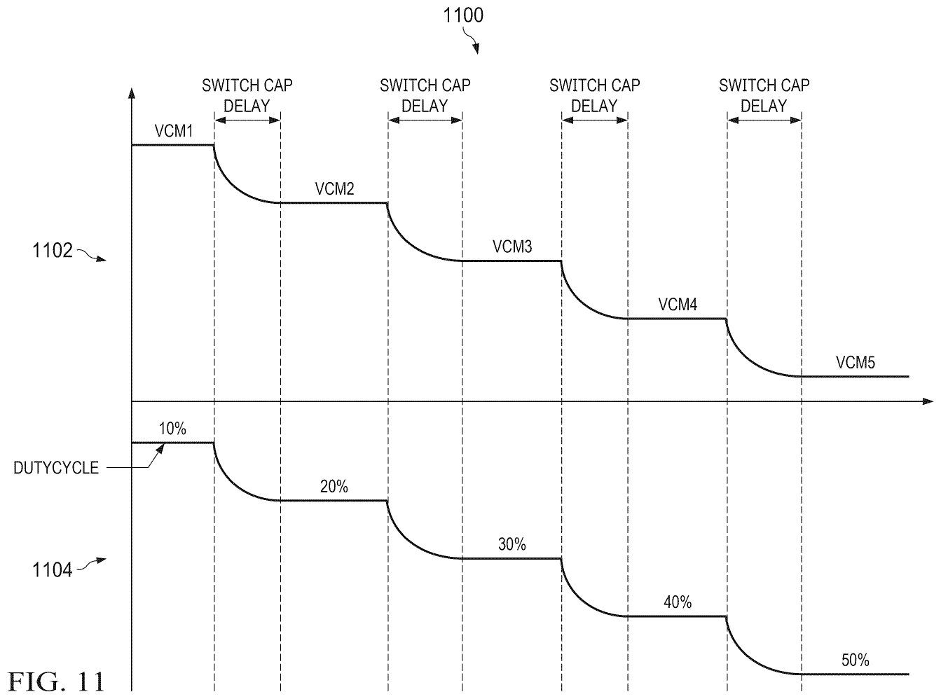

FIG. 11 illustrates a timing diagram 1100 that illustrates the VCM voltage 1102 provided by the buffer 920 and the corresponding duty cycle 1104 of the amplifier 108. For example, when the VCM voltage 1102 is at the first VCM1 voltage, the duty cycle 1104 is 10%. When the VCM voltage 1102 is at the second VCM2 voltage, the duty cycle 1104 is 20%. When the VCM voltage 1102 is at the second VCM2 voltage, the duty cycle 1104 is 30%. When the VCM voltage 1102 is at the second VCM2 voltage, the duty cycle 1104 is 40%. When the VCM voltage 1102 is at the second VCM2 voltage, the duty cycle 1104 is 50%. However, other voltages can be used that correspond to other duty cycles.

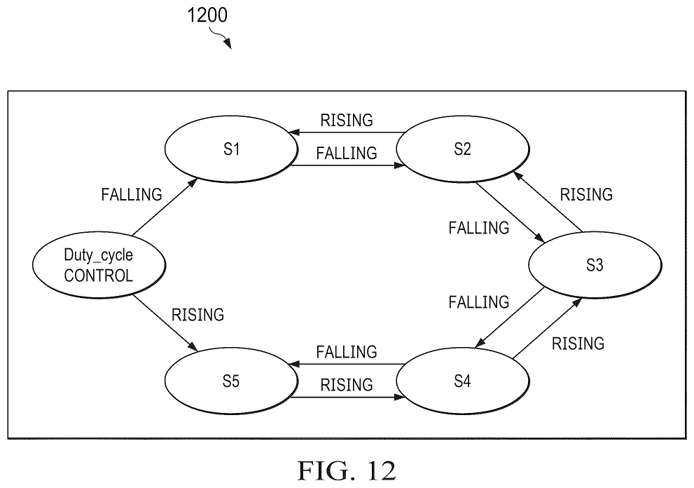

FIG. 12 is an example state diagram 1200 that illustrates example states when adjusting from a first state to a second state or vice versa. For example, when the duty cycle control changes from corresponding to a sleep state to a play state, the VCM voltage continues to decrease from first state S1 to a fifth state via the other states. In FIG. 12, the first state S1 corresponds to 10% duty cycle, the second state S2 corresponds to 20% duty cycle, the third state S3 corresponds to a 30% duty cycle, the fourth state S4 corresponds to a 40% duty cycle, and the fifth state S5 corresponds to a 50% duty cycle. When the duty cycle control changes from corresponding to a play state to a sleep state, the VCM voltage continues to increase from fifth state S5 to a first state S1 via the other states.

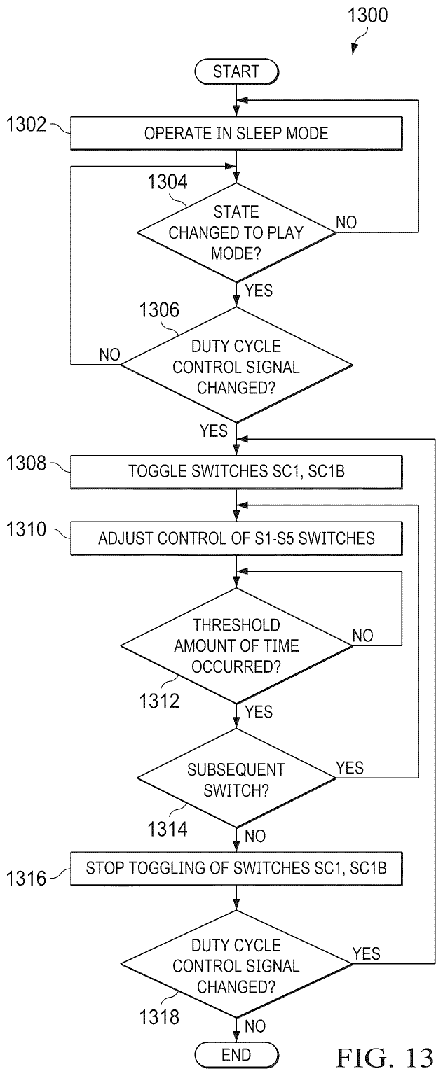

FIG. 13 is a flowchart representative of example machine readable instructions or example operations 1300 that may be executed, instantiated, or performed by programmable circuitry to control the switches 902, 904, 906, 908, 910, 912, 914 of FIG. 9 to reduce pops or clicks during a state or mode transition. The example machine-readable instructions or the example operations 1300 of FIG. 13 begin at block 1302, at which the VCM delay controller 922 is controlling the switches 902, 904, 906, 908, 910, 912, 914 to operate in sleep, off, or low power mode. For example, during sleep mode, the VCM delay controller 922 closes the switches 902, 912, 914 and opens the switch 904, 906, 908, 910 to cause the voltage at the output of the buffer 920 and the VCM input of the modulator 206 to be equal to the voltage of the first voltage source 901 (VCM1).

At block 1304, the VCM delay controller 922 determines if a state change to play mode has occurred. For example, the VCM delay controller 922 receives a state control signal from the control circuitry 228 of FIG. 2 that indicates whether a state change has occurred. If the VCM delay controller 922 determines that a state change to play mode has not occurred (block 1304: NO), control returns to block 1302. If the VCM delay controller 922 determines that a state change to play mode has occurred (block 1304: YES), the VCM delay controller 922 determines if a duty cycle control signal has changed (block 1306), for example from a logic high voltage to a logic low voltage). The duty cycle control signal is a signal received from the controller circuitry 228 to indicate that the duty cycle changes based on the state change.

If the VCM delay controller 922 determines that a duty cycle control signal has not changed (block 1306: NO), control returns to block 1304. If the VCM delay controller 922 determines that a duty cycle control signal has changed (block 1306: YES), the VCM delay controller 922 begins to toggle the switches 912, 914 open and close (block 1308). For example, the VCM delay controller 922 provides a first pulsing signal to the control terminal of the switch 912 and a second pulsing signal differential to the first pulsing signal to the control terminal of the switch 914 so that when the switch 912 is closed, the switch 914 is open and vice versa.

At block 1310, the VCM delay controller 922 adjusts the control of the S1-S5 switches to couple a subsequent voltage source to the filtering circuitry that includes the switches 912, 914 and the capacitors 916, 918. For example, if the first switch 902 was initially closed to couple the first voltage source 901 to the filtering circuitry, the VCM delay controller 922 opens the first switch 902 and close the second switch 904 to couple the second voltage source 903 to the filtering circuitry. At block 1312, the VCM delay controller 922 determines if a threshold amount of time has occurred. The threshold amount of time may be based on the capacitance of the capacitors 916, 918. If the VCM delay controller 922 determines that the threshold amount of time has not occurred (block 1312: NO), control returns to block 1312.

If the VCM delay controller 922 determines that the threshold amount of time has occurred (block 1312: YES), the VCM delay controller 922 determines if there is a subsequent switch that has not yet been closed (block 1314). For example, if the second switch 904 is currently closed, the VCM delay controller 922 determines that the third switch has yet to be closed because the switches are closed in order. If the VCM delay controller 922 determines that there is a subsequent switch that has not yet been closed (block 1314: YES), control returns to block 1310 to continue to close switches in order until the last switch has been enabled. If the VCM delay controller 922 determines that there is not a subsequent switch that has not yet been closed (block 1314: NO), the VCM delay controller 922 stops the togging of the switches 912, 914 and keeps the switches 912, 914 closed (block 1316). In this manner, the final voltage source 909 applies the VCM5 voltage to the buffer 920, thereby causing the amplifier 108 to operate at the play duty cycle (e.g., 50%). At block 1318, the VCM delay controller 922 determines if the duty cycle control signal has changed, thereby corresponding to a return back to a sleep state. If the VCM delay controller 922 determines that the duty cycle control signal has changed (block 1318: YES), control returns to block 1308 to repeat the process but in reverse order of switches. For example, enabling switch 910, then 908, then 906, . . . , and finally switch 902. If the VCM delay controller 922 determines that the duty cycle control signal has not changed (block 1318: NO), the instructions end.

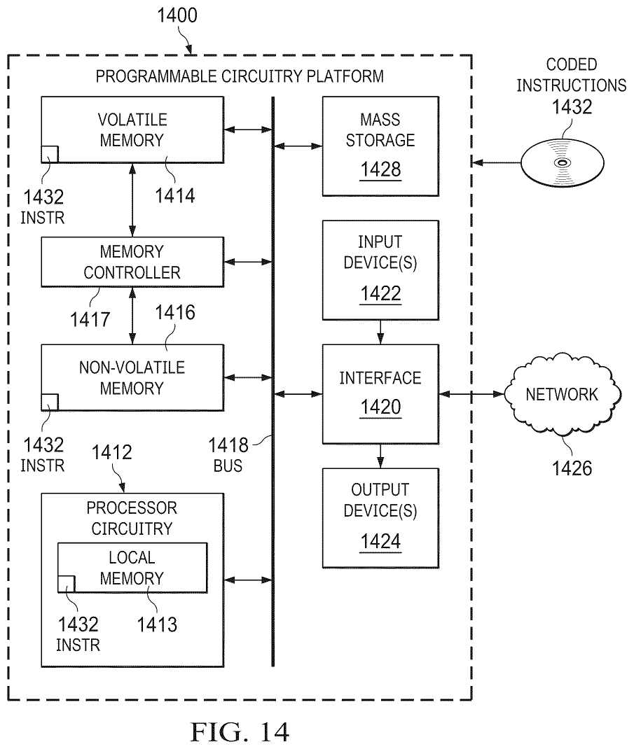

FIG. 14 is a block diagram of an example programmable circuitry platform 1400 structured to execute or instantiate the example machine-readable instructions or the example operations of FIGS. 8 and 13 to implement the VCM delay controller 226, 922 of FIG. 2 or 9. The programmable circuitry platform 1400 can be, for example, a personal computer, a infotainment system, a processing unit within an automotive device, a mobile device (e.g., a cell phone, a smart phone, a tablet such as an iPad™), a personal digital assistant (PDA), a DVD player, a CD player, a digital video recorder, a Blu-ray player, a gaming console, a headset (e.g., an augmented reality (AR) headset, a virtual reality (VR) headset, etc.) or other wearable device, or any other type of computing or electronic device.

The programmable circuitry platform 1400 of the illustrated example includes programmable circuitry 1412. The programmable circuitry 1412 of the illustrated example is hardware. For example, the programmable circuitry 1412 can be implemented by one or more integrated circuits, logic circuits, FPGAs, microprocessors, CPUs, GPUs, DSPs, or microcontrollers from any desired family or manufacturer. The programmable circuitry 1412 may be implemented by one or more semiconductor based (e.g., silicon based) devices. In this example, the programmable circuitry 1412 implements the VCM delay controller 226 of FIG. 2 or the VCM delay controller 922 of FIG. 9.

The programmable circuitry 1412 of the illustrated example includes a local memory 1413 (e.g., a cache, registers, etc.). The programmable circuitry 1412 of the illustrated example is in communication with main memory 1414, 1416, which includes a volatile memory 1414 and a non-volatile memory 1416, by a bus 1418. The volatile memory 1414 may be implemented by Synchronous Dynamic Random Access Memory (SDRAM), Dynamic Random Access Memory (DRAM), RAMBUS® Dynamic Random Access Memory (RDRAM®), or any other type of RAM device. The non-volatile memory 1416 may be implemented by flash memory or any other desired type of memory device. Access to the main memory 1414, 1416 of the illustrated example is controlled by a memory controller 1417. In some examples, the memory controller 1417 may be implemented by one or more integrated circuits, logic circuits, microcontrollers from any desired family or manufacturer, or any other type of circuitry to manage the flow of data going to and from the main memory 1414, 1416.

The programmable circuitry platform 1400 of the illustrated example also includes interface circuitry 1420. The interface circuitry 1420 may be implemented by hardware in any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1422 are connected to the interface circuitry 1420. The input device(s) 1422 permit(s) a user (e.g., a human user, a machine user, etc.) to enter data or commands into the programmable circuitry 1412. The input device(s) 1422 can be implemented by, for example, an audio sensor, a microphone, a camera (still or video), a keyboard, a button, a mouse, a touchscreen, a or a voice recognition system.

One or more output devices 1424 are also connected to the interface circuitry 1420 of the illustrated example. The output device(s) 1424 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, or speaker. The interface circuitry 1420 of the illustrated example, thus, typically includes a graphics driver card, a graphics driver chip, or graphics processor circuitry such as a GPU.

The interface circuitry 1420 of the illustrated example also includes a communication device such as a transmitter, a receiver, a transceiver, a modem, a residential gateway, a wireless access point, or a network interface to facilitate exchange of data with external machines (e.g., computing devices of any kind) by a network 1426. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1400 of the illustrated example also includes one or more mass storage discs or devices 1428 to store firmware, software, or data. Examples of such mass storage discs or devices 1428 include magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices or SSDs.

The machine readable instructions 1432, which may be implemented by the machine readable instructions of FIGS. 8 and 13, may be stored in the mass storage device 1428, in the volatile memory 1414, in the non-volatile memory 1416, or on at least one non-transitory computer readable storage medium such as a CD or DVD which may be removable.

While an example manner of implementing the VCM delay controller 226, 922 of FIG. 1 is illustrated in FIG. 2 or 9, one or more of the elements, processes, or devices illustrated in FIG. 2 or 9 may be combined, divided, re-arranged, omitted, eliminated, or implemented in any other way. Further, the example the VCM delay controller 226, 922 of FIG. 2 or 9, may be implemented by hardware alone or by hardware in combination with software and firmware. Thus, for example, any of the VCM delay controller 226, 922, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example the VCM delay controller 226, 922 of FIG. 2 or 9 may include one or more elements, processes, or devices in addition to, or instead of, those illustrated in FIG. 2 or 9, or may include more than one of any or all of the illustrated elements, processes and devices.

Flowchart(s) representative of example machine-readable instructions, which may be executed by programmable circuitry to at least one of implement or instantiate the VCM delay controller 226, 922 of FIG. 2 or 9 or representative of example operations which may be performed by programmable circuitry to at least one of implement or instantiate the VCM delay controller 226, 922 of FIG. 2 or 9, are shown in FIGS. 8 and 13. The machine-readable instructions may be one or more executable programs or portion(s) of one or more executable programs for execution by programmable circuitry such as the programmable circuitry 1412 shown in the example processor platform 1400 discussed below in connection with FIG. 14 and may be one or more function(s) or portion(s) of functions to be performed by programmable circuitry (e.g., an FPGA). In some examples, the machine-readable instructions cause an operation, a task, etc., to be carried out or performed in an automated manner in the real-world. As used herein, “automated” means without human involvement.

The program may be embodied in instructions (e.g., software or firmware) stored on one or more non-transitory computer readable or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 8 and 13, many other methods of implementing the example the VCM delay controller 226, 922 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C #, Perl, Python, JavaScript, HyperText Markup Language (HTML), Structured Query Language (SQL), Swift, etc.

As mentioned above, the example operations of FIGS. 8 and 13 may be implemented using executable instructions (e.g., computer readable or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

Descriptors “first,” “second,” “third,” etc. are used herein to identify multiple elements or components which may be referred to separately. Unless otherwise specified or known based on their context of use, such descriptors do not impute any meaning of priority, physical order, or arrangement in a list, or ordering in time but are merely used as labels for referring to multiple elements or components separately for ease of understanding the described examples. In some examples, the descriptor “first” may be used to refer to an element in the detailed description, while the same element may be referred to in a claim with a different descriptor such as “second” or “third.” In such instances, such descriptors are used merely for ease of referencing multiple elements or components.

In the description and in the claims, the terms “including” and “having,” and variants thereof are to be inclusive in a manner similar to the term “comprising” unless otherwise noted. Unless otherwise stated, “about,” “approximately,” or “substantially” preceding a value means +/−10 percent of the stated value. In another example, “about,” “approximately,” or “substantially” preceding a value means +/−5 percent of the stated value. IN another example, “about,” “approximately,” or “substantially” preceding a value means +/−1 percent of the stated value.

The terms “couple,” “coupled,” “couples,” and variants thereof, as used herein, may cover connections, communications, or signal paths that enable a functional relationship consistent with this description. For example, if device A generates a signal to control device B to perform an action, if a first example device A is coupled to device B, or if a second example device A is coupled to device B through intervening component C if intervening component C does not substantially alter the functional relationship between device A and device B, such that device B is controlled by device A via the control signal generated by device A. Moreover, the terms “couple,” “coupled”, “couples”, or variants thereof, includes an indirect or direct electrical or mechanical connection.

A device that is “configured to” perform a task or function may be configured (e.g., at least one of programmed or hardwired) at a time of manufacturing by a manufacturer to perform the function or may be configurable (or re-configurable) by a user after manufacturing to perform the function or other additional or alternative functions. The configuring may be through at least one firmware or software programming of the device, through a construction or layout of hardware components and interconnections of the device, or a combination thereof.

Although not all separately labeled in the FIGS. 1-4, components or elements of systems and circuits illustrated therein have one or more conductors or terminus that allow signals into or out of the components or elements. The conductors or terminus (or parts thereof) may be referred to herein as pins, pads, terminals (including inputs, outputs, reference terminals, and ground terminals, for instance), inputs, outputs, nodes, and interconnects.

As used herein, a “terminal” of a component, device, system, circuit, integrated circuit, or other electronic or semiconductor component, generally refers to a conductor such as a wire, trace, pin, pad, or other connector or interconnect that enables the component, device, system, etc., to electrically or mechanically connect to another component, device, system, etc. A terminal may be used, for instance, to receive or provide analog or digital electrical signals (or simply signals) or to electrically connect to a common or ground reference. Accordingly, an input or input is used to receive a signal from another component, device, system, etc. An output or output is used to provide a signal to another component, device, system, etc. Other terminals may be used to connect to a common, ground, or voltage reference, e.g., a reference terminal or ground terminal. A terminal of an IC or a PCB may also be referred to as a pin (a longitudinal conductor) or a pad (a planar conductor). A node refers to a point of connection or interconnection of two or more terminals. An example number of terminals and nodes may be shown. However, depending on particular circuitry or system topology, there may be more or fewer terminals and nodes. However, in some instances, “terminal,” “node,” “interconnect,” “pad,” and “pin” may be used interchangeably.

The term “or” as used, for example, in a form such as A, B, or C refers to any combination or subset of A, B, C such as (1) A alone, (2) B alone, (3) C alone, (4) A with B, (5) A with C, (6) B with C, or (7) A with B and with C.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Example methods, apparatus, systems, and articles of manufacture to regulate an amplifier are described herein. Further examples and combinations thereof include the following: Example 1 includes an amplifier circuit comprising a modulator having an input and an output, a comparator having an input and an output, the input of the comparator coupled to the output of the modulator, a first switch having a voltage source terminal and a second terminal, a second switch having a voltage source terminal and a second terminal, a resistor having a first terminal and a second terminal, the first terminal of the resistor coupled to the second terminal of the first switch and the second terminal of the second switch, a capacitor having a terminal coupled to the second terminal of the resistor, and a buffer having an input and an output, the input of the buffer coupled to the terminal of the capacitor and the second terminal of the resistor, the output of the buffer coupled to the input of the modulator.

Example 2 includes the amplifier circuit of example 1, further including a third switch having a first terminal and a second terminal, the first terminal of the third switch coupled to the second terminal of the first switch, the second terminal of the second switch, and the first terminal of the resistor, the second terminal of the third switch coupled to the second terminal of the resistor, the terminal of the capacitor and the input of the buffer.

Example 3 includes the amplifier circuit of example 2, further including control circuitry configured to control the first switch, the second switch, and the third switch responsive to a state change.

Example 4 includes the amplifier circuit of example 3, wherein the third switch further has a control terminal, wherein the control circuitry includes a first flip flop having a first terminal and a second terminal, the first terminal of the first flip flop configured to receive a clock signal, a second flip flop having a first terminal and a second terminal, the first terminal of the second flip flop coupled to the second terminal of the second flip flop, a first logic gate having a first input, a second input, and an output, the first input of the first logic gate configured to receive an amplifier state control signal, the second input of the first logic gate coupled to the second terminal of the second flip flop, a third flip flop having a first terminal, a second terminal and a third terminal, the first terminal of the third flip flop coupled to the output of the first logic gate, the second terminal configured to receive a duty cycle control signal, and a second logic gate having an input and an output, the input of the second logic gate coupled to the third terminal of the third flip flop, the output of the second logic gate coupled to the control terminal of the third switch.

Example 5 includes the amplifier circuit of example 1, further including driver circuitry having a first terminal and a second terminal, the first terminal of the driver circuitry coupled to the output of the comparator, and feedback resistor circuitry having a first terminal and a second terminal, the first terminal of the feedback resistor circuitry coupled to the second terminal of the driver circuitry, the second terminal of the feedback resistor circuitry coupled to the input of the modulator.

Example 6 includes the amplifier circuit of example 1, wherein the input of the buffer is a first input, the buffer having a second input coupled to the output of the buffer.

Example 7 includes the amplifier circuit of example 1, wherein the modulator includes a first amplifier having an input and an output, the input of the first amplifier being the input of the modulator, a second resistor having a first terminal and a second terminal, the first terminal of the second resistor coupled to the output of first the amplifier, and a second amplifier having a first input, a second input and an output, the first input of the second amplifier coupled to the second terminal of the second resistor, the second input of the second amplifier coupled to the output of the buffer, the output of the second amplifier coupled to the input of the comparator.

Example 8 includes the amplifier circuit of example 7, wherein the capacitor is a first capacitor, the modulated further includes a second capacitor having a first terminal and a second terminal, the first terminal of the second capacitor coupled to the output of the second amplifier, the second terminal of the second capacitor coupled to the input of the second amplifier and the second terminal of the second resistor, a third capacitor having a first terminal and a second terminal, the first terminal of the third capacitor coupled to the second terminal of the second capacitor, the second terminal of the second resistor, and the input of the second amplifier, the second terminal of the third capacitor coupled to the output of the first amplifier and the first terminal of the second resistor, and a fourth capacitor having a first terminal and a second terminal, the first terminal of the fourth capacitor coupled to the output of the first amplifier, the second terminal of the third capacitor, and the first terminal of the second resistor, the second terminal of the fourth capacitor coupled to the input of the first amplifier.

Example 9 includes an amplifier circuit comprising a modulator having an input and an output, a comparator having an input and an output, the input of the comparator coupled to the output of the modulator, a first switch having a voltage source terminal and a second terminal, a second switch having a voltage source terminal and a second terminal, a third switch having a first terminal and a second terminal, the first terminal of the third switch coupled to the second terminal of the first switch and the second terminal of the second switch, a first capacitor having a terminal, the terminal of the first capacitor coupled to the second terminal of the third switch, a fourth switch having a first terminal and a second terminal, the first terminal of the fourth switch coupled to the second terminal of the third switch and the first terminal of the first capacitor, a second capacitor having a terminal, the terminal of the second capacitor coupled to the second terminal of the fourth switch, and a buffer having an input and an output, the input of the buffer coupled to the terminal of the second capacitor and the second terminal of the fourth switch, the output of the buffer coupled to the input of the modulator.

Example 10 includes the amplifier circuit of example 9, further including control circuitry configured to control the first switch, the second switch, the third switch, and the fourth switch responsive to a state change.

Example 11 includes the amplifier circuit of example 9, further including driver circuitry having a first terminal and a second terminal, the first terminal of the driver circuitry coupled to the output of the comparator, and feedback resistor circuitry having a first terminal and a second terminal, the first terminal of the feedback resistor circuitry coupled to the second terminal of the driver circuitry, the second terminal of the feedback resistor circuitry coupled to the input of the modulator.

Example 12 includes the amplifier circuit of example 9, wherein the input of the buffer is a first input, the buffer having a second input, the second input of the buffer coupled to the output of the buffer.

Example 13 includes the amplifier circuit of example 9, wherein the modulator includes a first amplifier having an input and an output, the input of the first amplifier being the input of the modulator, a second resistor having a first terminal and a second terminal, the first terminal of the second resistor coupled to the output of first the amplifier, and a second amplifier having a first input, a second input and an output, the first input of the second amplifier coupled to the second terminal of the second resistor, the second input of the second amplifier coupled to the output of the buffer, the output of the second amplifier coupled to the input of the comparator.

Example 14 includes the amplifier circuit of example 13, wherein the modulated further includes a third capacitor having a first terminal and a second terminal, the first terminal of the third capacitor coupled to the output of the second amplifier, the second terminal of the third capacitor coupled to the input of the second amplifier and the second terminal of the second resistor, a fourth capacitor having a first terminal and a second terminal, the first terminal of the fourth capacitor coupled to the second terminal of the third capacitor, the second terminal of the second resistor, and the input of the second amplifier, the second terminal of the fourth capacitor coupled to the output of the first amplifier and the first terminal of the second resistor, and a fifth capacitor having a first terminal and a second terminal, the first terminal of the fifth capacitor coupled to the output of the first amplifier, the second terminal of the fourth capacitor, and the first terminal of the second resistor, the second terminal of the fifth capacitor coupled to the input of the first amplifier.

Example 15 includes an apparatus comprising an amplifier configured to convert an audio signal into a pulse width modulated signal, the amplifier including a modulator having a common mode terminal, a comparator coupled to the modulator, driver circuitry coupled to the comparator, and filtering circuitry coupled to the modulator and including a first switch having a voltage source terminal and a second terminal, a second switch a voltage source terminal and a second terminal, a third switch having a first terminal and a second terminal, the first terminal of the third switch coupled to the second terminal of the first switch, a capacitor having a terminal, the terminal of the capacitor coupled to the second terminal of the third switch, and a controller configured to adjust a common mode voltage provided to the common mode terminal of the modulator by controlling the first switch, the second switch, and the third switch.

Example 16 includes the apparatus of example 15, further including a processing unit coupled to the amplifier and configured to provide the audio signal, and a speaker configured to output audio based on the pulse width modulated signal.

Example 17 includes the apparatus of example 15, wherein the filtering circuitry further includes a resistor having a first terminal and a second terminal, the first terminal of the resistor coupled to the second terminal of the first switch, the second terminal of the second switch, and the first terminal of the third switch, the second terminal of the resistor coupled to the second terminal of the second switch and the terminal of the capacitor.

Example 18 includes the apparatus of example 15, wherein the capacitor is a first capacitor, the filtering circuitry further including a fourth switch having a first terminal and a second terminal, the first terminal of the fourth switch coupled to the second terminal of the third switch and the terminal of the first capacitor, and a second capacitor having a terminal and a second terminal, the terminal of the second capacitor coupled to the second terminal of the fourth switch.

Example 19 includes the apparatus of example 15, wherein the amplifier includes an input resistor having a terminal, and a feedback resistor having a first terminal and a second terminal, the second terminal of the feedback resistor coupled to the terminal of the input resistor, and wherein the modulator having an input and an output, the input of the modulator coupled to the second terminal of the input resistor and the second terminal of the feedback resistor, the comparator having a first signal generator input, a second input, and an output, the second input of the comparator coupled to the output of the modulator, and the driver circuitry having an input and an output, the input of the driver circuitry coupled to the output of the comparator, the output of the driver circuitry coupled to the first terminal of the feedback resistor.

Example 20 includes the apparatus of example 19, wherein the input resistor is a first input resistor, the feedback resistor is a first feedback resistor, the comparator is a first comparator, the driver circuitry is first driver circuitry, the input of the modulator is a first input, and the output of the modulator is a first output, the amplifier further including a second input resistor having a terminal, a second feedback resistor having a first terminal and a second terminal, the second terminal of the second feedback resistor coupled to the terminal of the second input resistor, the modulator having a second input and a second output, the second input of the modulator coupled to the second terminal of the second input resistor and the second terminal of the second feedback resistor, a second comparator having a first signal generator input, a second input, and an output, the second input of the second comparator coupled to the second output of the modulator, and second driver circuitry having an input and an output, the input of the second driver circuitry coupled to the output of the second comparator, the output of the second driver circuitry coupled to the first terminal of the second feedback resistor.

From the foregoing, it will be appreciated that example systems, apparatus, articles of manufacture, and methods have been described to regulate an amplifier. Described systems, apparatus, articles of manufacture, and methods improve the efficiency of using amplifiers by reducing the pops or clicks caused by mismatch in the amplifiers. Described systems, apparatus, articles of manufacture, and methods are accordingly directed to one or more improvement(s) in the operation of a machine such as an amplifier or other electronic device.

Modifications are possible in the described examples, and other examples are possible, within the scope of the claims.

What is claimed is:

1. An amplifier circuit comprising:
a modulator having an input and an output;
a comparator having an input and an output, the input of the comparator coupled to the output of the modulator;
a first switch having a voltage source terminal and a second terminal;
a second switch having a voltage source terminal and a second terminal;
a resistor having a first terminal and a second terminal, the first terminal of the resistor coupled to the second terminal of the first switch and the second terminal of the second switch;
a capacitor having a terminal coupled to the second terminal of the resistor; and a buffer having an input and an output, the input of the buffer coupled to the terminal of the capacitor and the second terminal of the resistor, the output of the buffer coupled to the input of the modulator.

2. The amplifier circuit of claim 1, further including a third switch having a first terminal and a second terminal, the first terminal of the third switch coupled to the second terminal of the first switch, the second terminal of the second switch, and the first terminal of the resistor, the second terminal of the third switch coupled to the second terminal of the resistor, the terminal of the capacitor and the input of the buffer.

3. The amplifier circuit of claim 2, further including control circuitry configured to control the first switch, the second switch, and the third switch responsive to a state change.

4. The amplifier circuit of claim 3, wherein the third switch further has a control terminal, wherein the control circuitry includes:
a first flip flop having a first terminal and a second terminal, the first terminal of the first flip flop configured to receive a clock signal;
a second flip flop having a first terminal and a second terminal, the first terminal of the second flip flop coupled to the second terminal of the second flip flop;
a first logic gate having a first input, a second input, and an output, the first input of the first logic gate configured to receive an amplifier state control signal, the second input of the first logic gate coupled to the second terminal of the second flip flop;
a third flip flop having a first terminal, a second terminal and a third terminal, the first terminal of the third flip flop coupled to the output of the first logic gate, the second terminal configured to receive a duty cycle control signal; and
a second logic gate having an input and an output, the input of the second logic gate coupled to the third terminal of the third flip flop, the output of the second logic gate coupled to the control terminal of the third switch.

5. The amplifier circuit of claim 1, further including:
driver circuitry having a first terminal and a second terminal, the first terminal of the driver circuitry coupled to the output of the comparator; and
feedback resistor circuitry having a first terminal and a second terminal, the first terminal of the feedback resistor circuitry coupled to the second terminal of the driver circuitry, the second terminal of the feedback resistor circuitry coupled to the input of the modulator.

6. The amplifier circuit of claim 1, wherein the input of the buffer is a first input, the buffer having a second input coupled to the output of the buffer.

7. The amplifier circuit of claim 1, wherein the modulator includes:
a first amplifier having an input and an output, the input of the first amplifier being the input of the modulator;
a second resistor having a first terminal and a second terminal, the first terminal of the second resistor coupled to the output of first the amplifier; and
a second amplifier having a first input, a second input and an output, the first input of the second amplifier coupled to the second terminal of the second resistor, the second input of the second amplifier coupled to the output of the buffer, the output of the second amplifier coupled to the input of the comparator.

8. The amplifier circuit of claim 7, wherein the capacitor is a first capacitor, the modulated further includes:
a second capacitor having a first terminal and a second terminal, the first terminal of the second capacitor coupled to the output of the second amplifier, the second terminal of the second capacitor coupled to the input of the second amplifier and the second terminal of the second resistor;
a third capacitor having a first terminal and a second terminal, the first terminal of the third capacitor coupled to the second terminal of the second capacitor, the second terminal of the second resistor, and the input of the second amplifier, the second terminal of the third capacitor coupled to the output of the first amplifier and the first terminal of the second resistor; and
a fourth capacitor having a first terminal and a second terminal, the first terminal of the fourth capacitor coupled to the output of the first amplifier, the second terminal of the third capacitor, and the first terminal of the second resistor, the second terminal of the fourth capacitor coupled to the input of the first amplifier.

9. An amplifier circuit comprising:
a modulator having an input and an output;
a comparator having an input and an output, the input of the comparator coupled to the output of the modulator;
a first switch having a voltage source terminal and a second terminal;
a second switch having a voltage source terminal and a second terminal;
a third switch having a first terminal and a second terminal, the first terminal of the third switch coupled to the second terminal of the first switch and the second terminal of the second switch;
a first capacitor having a terminal, the terminal of the first capacitor coupled to the second terminal of the third switch;
a fourth switch having a first terminal and a second terminal, the first terminal of the fourth switch coupled to the second terminal of the third switch and the first terminal of the first capacitor;
a second capacitor having a terminal, the terminal of the second capacitor coupled to the second terminal of the fourth switch; and
a buffer having an input and an output, the input of the buffer coupled to the terminal of the second capacitor and the second terminal of the fourth switch, the output of the buffer coupled to the input of the modulator.

10. The amplifier circuit of claim 9, further including control circuitry configured to control the first switch, the second switch, the third switch, and the fourth switch responsive to a state change.

11. The amplifier circuit of claim 9, further including:
driver circuitry having a first terminal and a second terminal, the first terminal of the driver circuitry coupled to the output of the comparator; and
feedback resistor circuitry having a first terminal and a second terminal, the first terminal of the feedback resistor circuitry coupled to the second terminal of the driver circuitry, the second terminal of the feedback resistor circuitry coupled to the input of the modulator.

12. The amplifier circuit of claim 9, wherein the input of the buffer is a first input, the buffer having a second input, the second input of the buffer coupled to the output of the buffer.

13. The amplifier circuit of claim 9, wherein the modulator includes:
a first amplifier having an input and an output, the input of the first amplifier being the input of the modulator;
a second resistor having a first terminal and a second terminal, the first terminal of the second resistor coupled to the output of first the amplifier; and
a second amplifier having a first input, a second input and an output, the first input of the second amplifier coupled to the second terminal of the second resistor, the second input of the second amplifier coupled to the output of the buffer, the output of the second amplifier coupled to the input of the comparator.

14. The amplifier circuit of claim 13, wherein the modulated further includes:
a third capacitor having a first terminal and a second terminal, the first terminal of the third capacitor coupled to the output of the second amplifier, the second terminal of the third capacitor coupled to the input of the second amplifier and the second terminal of the second resistor;
a fourth capacitor having a first terminal and a second terminal, the first terminal of the fourth capacitor coupled to the second terminal of the third capacitor, the second terminal of the second resistor, and the input of the second amplifier, the second terminal of the fourth capacitor coupled to the output of the first amplifier and the first terminal of the second resistor; and
a fifth capacitor having a first terminal and a second terminal, the first terminal of the fifth capacitor coupled to the output of the first amplifier, the second terminal of the fourth capacitor, and the first terminal of the second resistor, the second terminal of the fifth capacitor coupled to the input of the first amplifier.

15. An apparatus comprising:
an amplifier configured to convert an audio signal into a pulse width modulated signal, the amplifier including:
a modulator having a common mode terminal;
a comparator coupled to the modulator;
driver circuitry coupled to the comparator; and
filtering circuitry coupled to the modulator and including:
a first switch having a voltage source terminal and a second terminal;
a second switch a voltage source terminal and a second terminal;
a third switch having a first terminal and a second terminal, the first terminal of the third switch coupled to the second terminal of the first switch;
a capacitor having a terminal, the terminal of the capacitor coupled to the second terminal of the third switch; and
a controller configured to adjust a common mode voltage provided to the common mode terminal of the modulator by controlling the first switch, the second switch, and the third switch.

16. The apparatus of claim 15, further including:
a processing unit coupled to the amplifier and configured to provide the audio signal; and
a speaker configured to output audio based on the pulse width modulated signal.

17. The apparatus of claim 15, wherein the filtering circuitry further includes a resistor having a first terminal and a second terminal, the first terminal of the resistor coupled to the second terminal of the first switch, the second terminal of the second switch, and the first terminal of the third switch, the second terminal of the resistor coupled to the second terminal of the second switch and the terminal of the capacitor.

18. The apparatus of claim 15, wherein the capacitor is a first capacitor, the filtering circuitry further including:
a fourth switch having a first terminal and a second terminal, the first terminal of the fourth switch coupled to the second terminal of the third switch and the terminal of the first capacitor; and
a second capacitor having a terminal and a second terminal, the terminal of the second capacitor coupled to the second terminal of the fourth switch.

19. The apparatus of claim 15, wherein the amplifier includes:
an input resistor having a terminal; and
a feedback resistor having a first terminal and a second terminal, the second terminal of the feedback resistor coupled to the terminal of the input resistor, and wherein:
the modulator having an input and an output, the input of the modulator coupled to the second terminal of the input resistor and the second terminal of the feedback resistor;
the comparator having a first signal generator input, a second input, and an output, the second input of the comparator coupled to the output of the modulator; and
the driver circuitry having an input and an output, the input of the driver circuitry coupled to the output of the comparator, the output of the driver circuitry coupled to the first terminal of the feedback resistor.

20. The apparatus of claim 19, wherein the input resistor is a first input resistor, the feedback resistor is a first feedback resistor, the comparator is a first comparator, the driver circuitry is first driver circuitry, the input of the modulator is a first input, and the output of the modulator is a first output, the amplifier further including:
a second input resistor having a terminal;
a second feedback resistor having a first terminal and a second terminal, the second terminal of the second feedback resistor coupled to the terminal of the second input resistor;
the modulator having a second input and a second output, the second input of the modulator coupled to the second terminal of the second input resistor and the second terminal of the second feedback resistor;
a second comparator having a first signal generator input, a second input, and an output, the second input of the second comparator coupled to the second output of the modulator; and
second driver circuitry having an input and an output, the input of the second driver circuitry coupled to the output of the second comparator, the output of the second driver circuitry coupled to the first terminal of the second feedback resistor.
